(19) United States
(12) Patent Application Publication
(10) Pub. No.: US 2026/0179515 A1
(43) Pub. Date: Jun. 25, 2026

(54) DISPLAY DEVICE AND ELECTRONIC APPARATUS INCLUDING THE SAME

(71) Applicant: Samsung Display Co., LTD., Yongin-si (KR)

(72) Inventor: Jiwon LEE, Yongin-si (KR)

(21) Appl. No.: 19/423,012

(22) Filed: Dec. 17, 2025

(30) Foreign Application Priority Data
Dec. 20, 2024 (KR) 10-2024-0193313

(51) Int. Cl. G09G 3/00; G09G 3/3233

(52) U.S. Cl. CPC G09G 3/035; G09G 3/3233; G09G 2300/0426; G09G 2300/0819; G09G 2300/0852; G09G 2300/0861; G09G 2320/0233; G09G 2320/0257; G09G 2320/0276; G09G 2330/023; G09G 2330/04

(57) ABSTRACT

A display device includes island portions each including a light-emitting element and a pixel driving circuit electrically connected to the light-emitting element, bridge portions each connected between two adjacent island portions among the island portions, and force portions apart from each other in a plan view, where a first force portion among the force portions overlaps at least two bridge portions disposed adjacent to each other among the bridge portions in the plan view.

This application claims priority to Korean Patent Application No. 10-2024-0193313, filed on Dec. 20, 2024, and all the benefits accruing therefrom under 35 U.S.C. § 119, the content of which in its entirety is herein incorporated by reference.

### BACKGROUND

### (1) Field

Embodiments of the invention relate to a display device and an electronic apparatus including the same.

### (2) Description of the Related Art

With the development of display devices that visually display various electrical signals, various display devices having excellent characteristics such as thinness, light weight, low power consumption, and the like have been introduced. For example, flexible display devices that are foldable or rollable in a roll shape have been introduced. Recently, research and development into display devices of various structures, such as stretchable display devices that may change into various shapes, are actively in progress.

### SUMMARY

Embodiments of the invention provide a display device and an electronic apparatus including the same.

In an embodiment of the invention, a display device includes: island portions each including a light-emitting element and a pixel driving circuit electrically connected to the light-emitting element; bridge portions each connected between two adjacent island portions among the island portions; and force portions apart from each other in a plan view, where a first force portion among the force portions overlaps at least two bridge portions adjacent to each other among the bridge portions in the plan view.

In an embodiment, a modulus of the first force portion may be greater than a modulus of each of the at least two bridge portions.

In an embodiment, the modulus of the first force portion may be greater than about 27 megapascals (MPa) and equal to or less than about 12 gigapascals (GPa).

In an embodiment, the first force portion may include a first polymer material.

In an embodiment, the first force portion may further include a layer including a second polymer material different from the first polymer material.

In an embodiment, the first polymer material may include an ultraviolet (UV)-curable polymer, and the second polymer material may include a thermo-reactive polymer.

In an embodiment, the display device may be stretchable, and an overlapping area of the first force portion and the at least two bridge portions when the display device is in a stretched state may be less than an overlapping area of the first force portion and the at least two bridge portions when the display device is in a non-stretched state.

In an embodiment, each of the bridge portions may include a straight portion and a curved portion, and the first force portion may overlap the curved portion of each of the at least two bridge portions in the plan view.

In an embodiment, each of the bridge portions may include: a first curved portion connected to one of the two adjacent island portions; a second curved portion connected to the other of the two adjacent island portions; and the straight portion connecting the first curved portion and the second curved portion to each other.

In an embodiment, the display device may further include an upper protective layer disposed on the force portions, where the upper protective layer may include elastomer.

In an embodiment, the display device may further include a first adhesive layer disposed between the force portions and the upper protective layer, where the first adhesive layer may include an adhesive material.

In an embodiment, the force portions may be disposed in the first adhesive layer.

In an embodiment, each of the force portions may have, in the plan view, a circular shape, an elliptical shape, or a polygonal shape.

In an embodiment of the invention, an electronic apparatus including a display device, where the display device includes: a display panel including island portions and bridge portions each connected between two adjacent island portions among the island portions; and force portions arranged on the display panel and apart from each other in a plan view, where each of the bridge portions includes a curved portion and a straight portion, and where a first force portion among the force portions overlaps the curved portion of each of at least two bridge portions adjacent to each other among the bridge portions in the plan view.

In an embodiment, a modulus of the first force portion may be greater than a modulus of each of the at least two bridge portions.

In an embodiment, the modulus M of the first force portion may be greater than about 27 MPa and equal to or less than about 12 GPa.

In an embodiment, the first force portion may include a first polymer material.

In an embodiment, the first polymer material may include a UV-curable polymer.

In an embodiment, the first force portion may further include a layer including a second polymer material different from the first polymer material, and the second polymer material may include a thermo-reactive polymer.

In an embodiment, the display panel is stretchable, and an overlapping area of the first force portion and the at least two bridge portions when the display panel is in a stretched state may be less than an overlapping area of the first force portion and the at least two bridge portions when the display device is in a non-stretched state.

In an embodiment, the display device of the electronic apparatus may further include an upper protective layer disposed on the force portions, where the upper protective layer may include elastomer.

In an embodiment, The display device of the electronic apparatus may further include a first adhesive layer disposed between the force portions and the upper protective layer, where the first adhesive layer may include an adhesive material.

In an embodiment, the force portions may be disposed in the first adhesive layer.

In an embodiment, each of the force portions may have, in the plan view, a circular shape, an elliptical shape, or a polygonal shape.

In an embodiment, the electronic apparatus may further include a strain sensor which measures changes in a physical quantity according to stretching of the display panel.

According to embodiments of the invention, while a display device and/or an electronic apparatus is stretched, defects of the display device and/or the electronic apparatus due to stress applied to bridge portions may be effectively prevented by providing force portions to overlap the bridge portions.

### BRIEF DESCRIPTION OF THE DRAWINGS

FIG. 1 is a schematic perspective view of a display device according to an embodiment of the invention.

FIGS. 2A and 2B are perspective views of the display device of FIG. 1 stretched in a first direction.

FIG. 2C is a perspective view of the display device of FIG. 1 stretched in a second direction.

FIG. 2D is a perspective view of the display device of FIG. 1 stretched in the first direction and the second direction.

FIG. 2E is a perspective view of the display device of FIG. 1 stretched in a third direction.

FIG. 3A is a schematic cross-sectional view of a display device according to an embodiment of the invention.

FIG. 3B is a schematic plan view of a display panel of a display device according to an embodiment of the invention.

FIG. 4A is an enlarged plan view of a portion of a display device, showing a region IV of FIG. 3B according to an embodiment of the invention.

FIG. 4B is an enlarged plan view of a portion of a display panel, showing a display area of FIG. 3B according to an embodiment of the invention.

FIGS. 5A and 5B are respectively schematic cross-sectional views of a first island portion and a first bridge portion in a display area of a display panel according to an embodiment of the invention.

FIGS. 6A to 6C are respectively equivalent circuit diagrams of a sub-pixel of a display device according to an embodiment of the invention.

FIGS. 7A and 7B are schematic cross-sectional views of a light-emitting element of a display panel according to an embodiment of the invention.

FIGS. 8A to 8C are respectively excerpted plan views of a portion of a display area of a display device according to an embodiment of the invention.

FIGS. 9A and 9B are respectively cross-sectional views of a portion of a display area of a display device according to an embodiment of the invention.

FIG. 10 is a cross-sectional view of a portion of a display panel according to an embodiment of the invention.

FIG. 11 is a plan view of a pixel driving circuit portion and a wiring of a display panel according to an embodiment of the invention.

FIG. 12A is a plan view of a display device in a non-stretched state, and FIG. 12B is a plan view of a display device in a stretched state.

FIGS. 13A to 13E are cross-sectional views showing processes in a method of manufacturing a force portion according to an embodiment of the invention.

FIG. 14A is a schematic perspective view of an electronic apparatus including a display device according to an embodiment of the invention.

FIG. 14B is a schematic block diagram of an electronic apparatus including a display device according to an embodiment of the invention.

FIGS. 15A to 15D are respectively schematic perspective views of an electronic apparatus including a display device according to an embodiment of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

In It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value n.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In the case where a certain embodiment may be implemented differently, a specific process order may be performed in the order different from the described order. As an example, two processes successively described may be simultaneously performed substantially and performed in the opposite order of the described order.

In embodiments below, when a layer, region, or element is referred to as being connected, it includes not only a case where the layer, region, or element is directly connected, but also a case where the layer, region, or element is indirectly connected with another layer, region, or element disposed therebetween. For example, in the specification, when a layer, region, or element is referred to as being electrically connected, it represents a case where the layer, region, or element is directly electrically connected and/or a case where the layer, region, or element may be indirectly electrically connected with another layer, region, or element disposed therebetween.

The x axis, the y axis and the z axis are not limited to three axes of the rectangular coordinate system, and may be interpreted in a broader sense including the same. For example, x axis, y axis, and z axis may be perpendicular to one another, or may represent different directions that are not perpendicular to one another.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

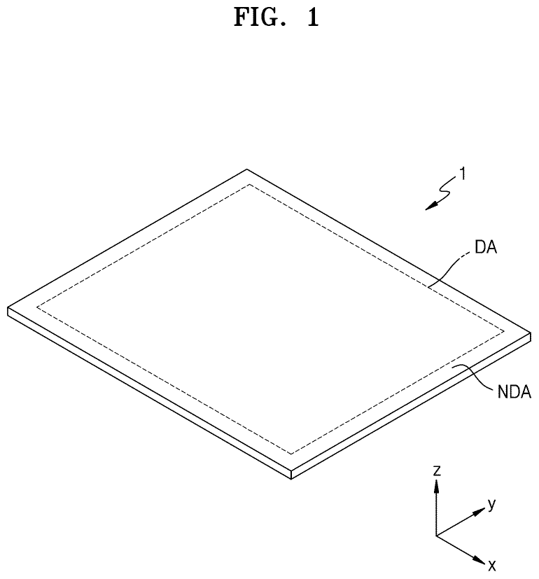

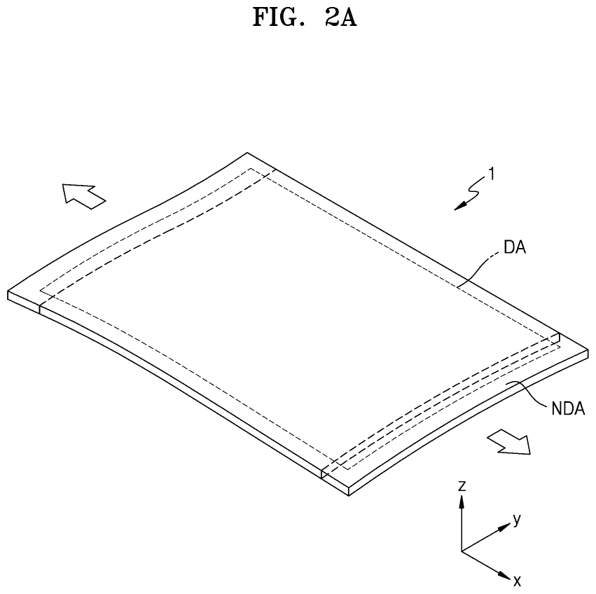

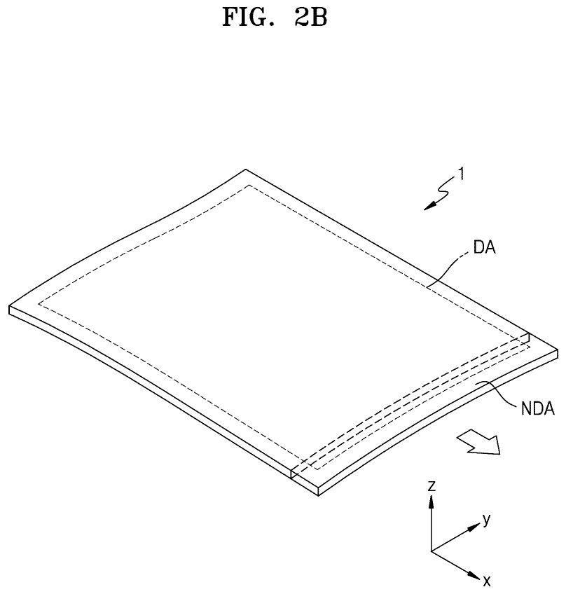

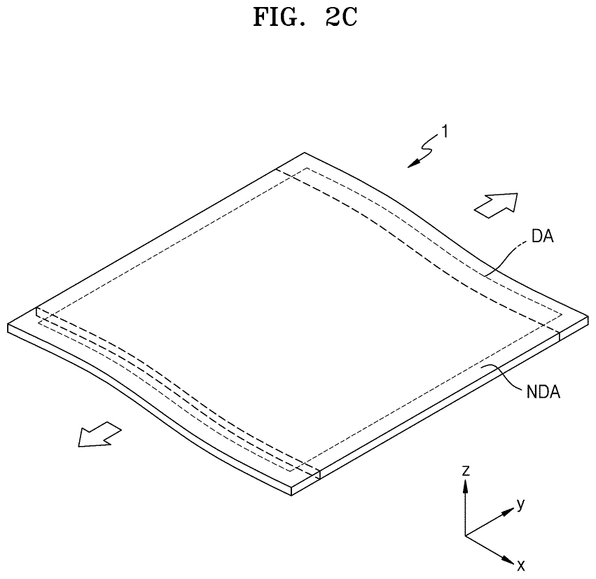

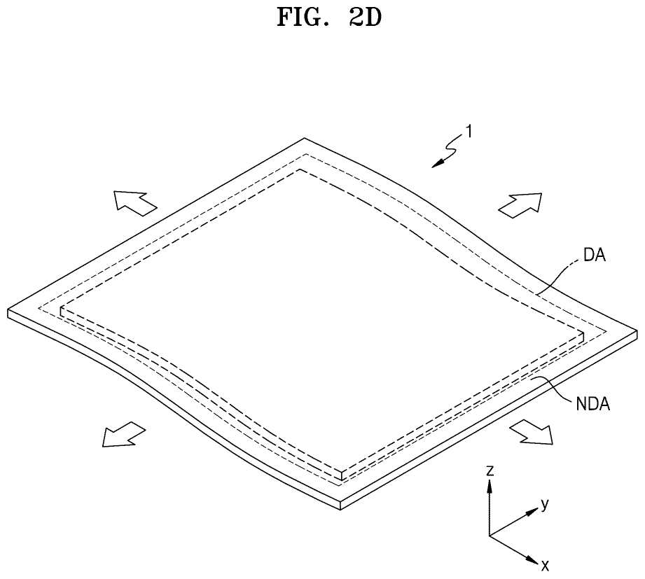

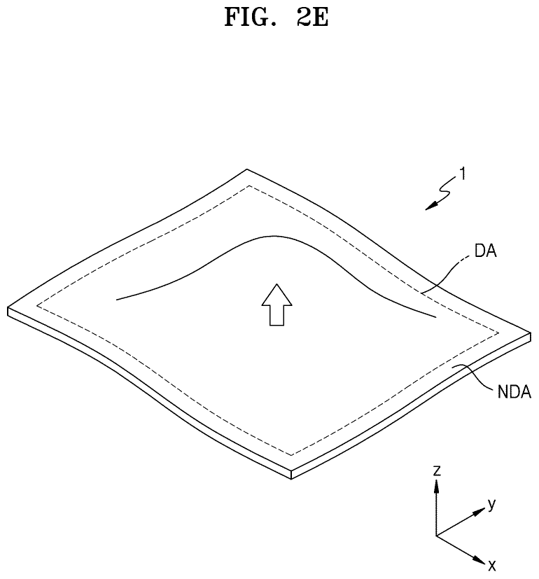

FIG. 1 is a schematic perspective view of a display device 1 according to an embodiment of the invention. FIGS. 2A and 2B are perspective views of the display device 1 of FIG. 1 stretched in a first direction. FIG. 2C is a perspective view of the display device 1 of FIG. 1 stretched in a second direction. FIG. 2D is a perspective view of the display device of FIG. 1 stretched in the first direction and the second direction. FIG. 2E is a perspective view of the display device 1 of FIG. 1 stretched in a third direction.

Referring to FIG. 1, an embodiment of the display device 1 may include a display area DA and a non-display area NDA. The display area DA may include a plurality of pixels. The display device 1 may provide preset images by using light emitted from the plurality of pixels. The non-display area NDA may be disposed outside the display area DA. The non-display area NDA is a region in which the pixels are not disposed and may surround the display area DA entirely.

In an embodiment, the display device 1 may stretch or shrink in various directions. The display device 1 may be stretched in the first direction (e.g., an x direction and/or −x direction) by an external force exerted by an external object or a user. In an embodiment, as shown in FIGS. 2A and 2B, the display area DA and/or the non-display area NDA of the display device 1 may be stretched in the first direction (e.g., the x direction and/or −x direction). In an embodiment, as shown in FIG. 2A, the display area DA and/or the non-display area NDA may be stretched in the x direction and −x direction, or as shown in FIG. 2B, be stretched in the x direction with one side of the display device 1 fixed.

The display device 1 may be stretched in the second direction (e.g., a y direction and/or −y direction) by an external force exerted by an external object or a user. In an embodiment, as shown in FIG. 2C, the display area DA and/or the non-display area NDA of the display device 1 may be stretched in the y direction and −y direction. In another embodiment, the display device 1 may be stretched in the y direction or −y direction with one side of the display device 1 fixed.

The display device 1 may be stretched in a plurality of directions, for example, the first direction (e.g., x direction and/or −x direction) and the second direction (e.g., y direction and/or −y direction) by external force exerted by an external object or a portion of a person's body. In an embodiment, as shown in FIG. 2D, the display area DA and/or the non-display area NDA of the display device 1 may be stretched in the ±x directions and ±y directions.

The display device 1 may be stretched in a third direction (e.g., a z direction and/or −z direction) by an external force exerted by an external object or a portion of a person's body. In an embodiment, FIG. 2E shows that a portion of the display device 1, for example, a partial region of the display area DA protrudes in the z direction. In another embodiment, a portion of the display device 1, for example, a partial region of the display area DA may protrude in the −z direction (or be recessed in the z direction).

Although FIGS. 2A to 2E show an embodiment where the display device 1 is stretched in the first direction, the second direction, and/or the third direction, the invention is not limited thereto. In another embodiment, the display device 1 may be variously transformed into an irregular shape, such as being bent or twisted along two or more axes.

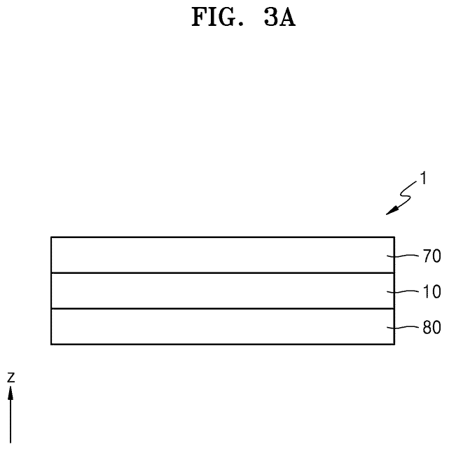

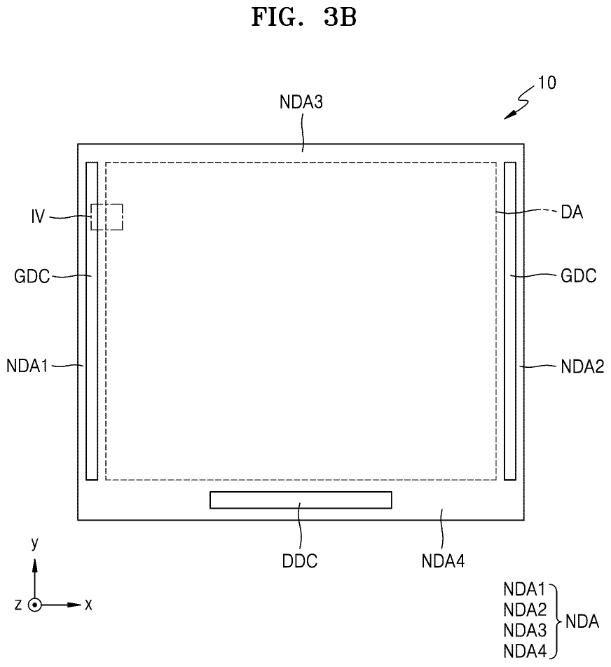

FIG. 3A is a schematic cross-sectional view of the display device 1 according to an embodiment of the invention.

Referring to FIG. 3A, an embodiment of the display device 1 may include a display panel 10, an upper layer 70 disposed on a first surface (e.g., an upper surface) of the display panel 10, and a lower layer 80 disposed on a second surface (e.g., a lower surface) which is the opposite side to the first surface (e.g., the upper surface) of the display panel 10.

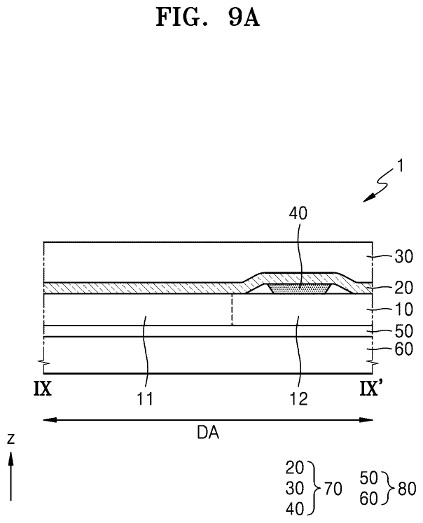

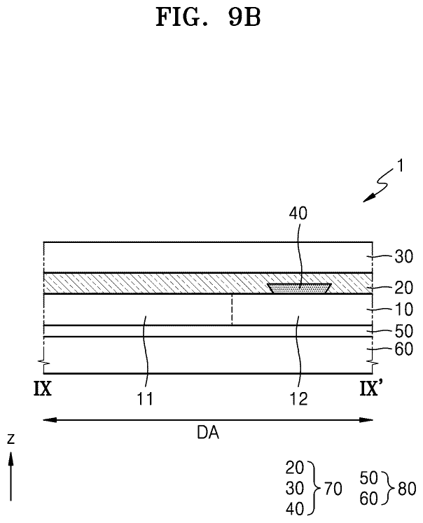

The display panel 10 may include light-emitting elements corresponding to the pixels, and pixel driving circuit portions electrically connected to the light-emitting elements. The upper layer 70 and the lower layer 80 may respectively protect the first surface and the second surface of the display panel 10. The upper layer 70 may include a structure for preventing a portion of the display panel 10 from being disconnected by the stress. Specific structures of the upper layer 70 and the lower layer 80 will be described later in greater detail with reference to FIGS. 9A and 9B.

FIG. 3B is a schematic plan view of the display panel 10 of the display device 1 (FIG. 3A) according to an embodiment of the invention.

In an embodiment, the display panel 10 may include the plurality of pixels arranged in the display area DA. Each pixel may include sub-pixels emitting light of different colors. A light-emitting element corresponding to each sub-pixel may be disposed in the display area DA. A circuit may be located in the non-display area NDA around the display area DA, and the circuit provides electrical signals to light-emitting elements disposed in the display area DA and transistors electrically connected to the light-emitting elements. A gate driving circuit GDC may be disposed in each of a first non-display area NDA1 and a second non-display area NDA2 disposed on two opposite sides with the display area DA therebetween. The gate driving circuit GDC of the display panel 10 may include drivers for providing electrical signals to a gate electrode of each of transistors electrically connected to the light-emitting elements. FIG. 3B shows an embodiment where the gate driving circuit GDC is disposed in each of the first non-display area NDA1 and the second non-display area NDA2, the invention is not limited thereto. In another embodiment, the gate driving circuit GDC may be disposed in one of the first non-display area NDA1 and the second non-display area NDA2.

A data driving circuit DDC of the display panel 10 may be disposed in a third non-display area NDA3 and/or a fourth non-display area NDA4 connecting the first non-display area NDA1 and the second non-display area NDA2 to each other. In an embodiment, it is shown in FIG. 3B that the data driving circuit DDC is disposed in the fourth non-display area NDA4. In another embodiment, the data driving circuit DDC may be disposed in each of the third non-display area NDA3 and fourth non-display area NDA4.

Although FIG. 3B shows an embodiment where the data driving circuit DDC is disposed in the fourth non-display area NDA4 of the display panel 10, the invention is not limited thereto. In another embodiment, the display panel 10 may further include a flexible circuit board (not shown) electrically connected through a terminal section (not shown) disposed in the fourth non-display area NDA4, and the data driving circuit DDC may be disposed on the flexible circuit board.

Referring to FIGS. 3A and 3B, in an embodiment, an elongation of the non-display area NDA of the display device 1 may be equal to or less than an elongation of the display DA. In an embodiment, an elongation of the non-display area NDA may be different for each region. In an embodiment, for example, the first non-display area NDA1, the second non-display area NDA2, and the third non-display area NDA3 may have substantially the same elongation rate, but an elongation of the fourth non-display area NDA4 may be less than an elongation of each of the first non-display area NDA1, the second non-display area NDA2, and the third non-display area NDA3. In the disclosure, an elongation denotes a numerical value representing a change (ΔL/L) in length by which the display device 1 (FIG. 3A) or the display panel 10 may be stretched without damage to the display device 1 or the display panel 10 when external force is applied to the display device 1 or the display panel 10. Here, ΔL denotes the amount of change in length of the display device 1 or the display panel 10, and L denotes an initial length of the display device 1.

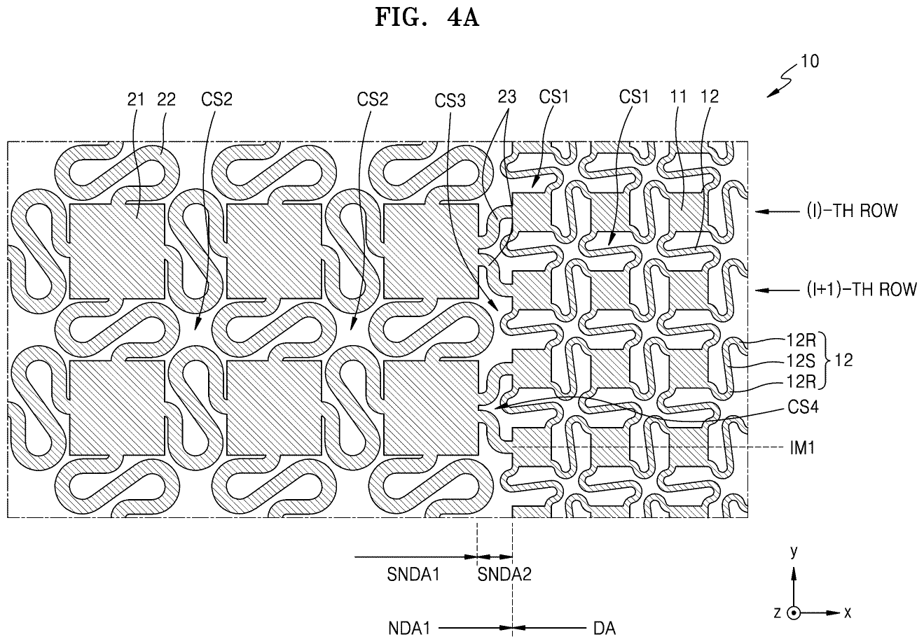

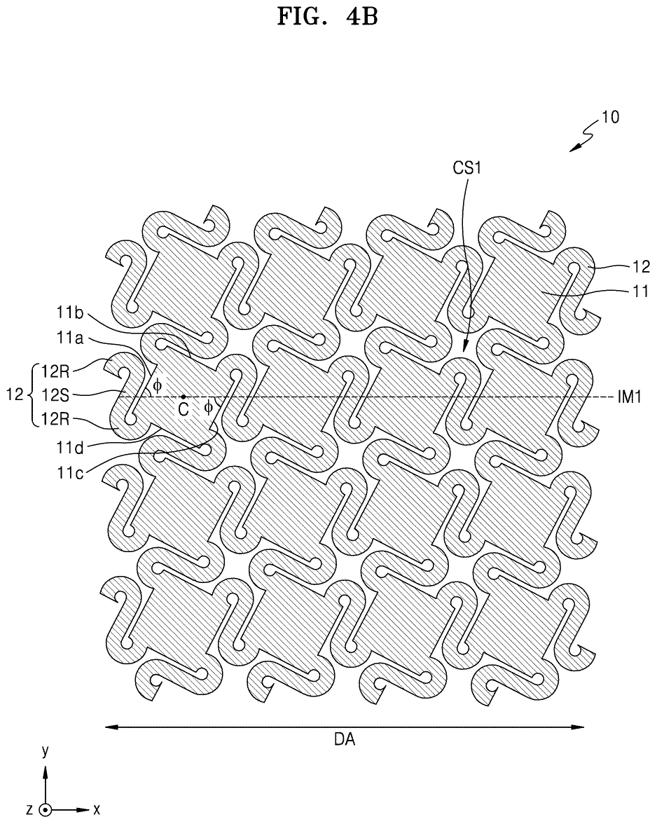

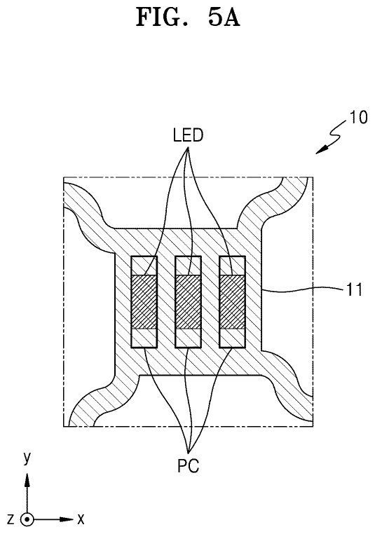

FIG. 4A is an enlarged plan view of a portion of the display panel 10, showing a region IV of FIG. 3B according to an embodiment of the invention.

Referring to FIG. 4A, an embodiment of the display panel 10 may include first island portions 11 and first bridge portions 12 connecting adjacent first island portions 11 to each other, where the first island portions 11 are apart from each other in the first direction (e.g., x direction or −x direction) and the second direction (e.g., y direction or −y direction) in the display area DA.

The first bridge portions 12 may be apart from each other by a first opening CS1 located between the first bridge portions 12. The first bridge portion 12 may have a serpentine shape. In an embodiment, for example, as shown in FIG. 4A, the first bridge portion 12 may have a shape of an approximate ‘letter S’ (or S-like shape) such as including two curved portions 12R and a straight portion 12S between the two curved portions 12R.

Each first island portion 11 may be connected to a plurality of first bridge portions 12. In an embodiment, for example, each first island portion 11 may be connected to four first bridge portions 12. Two first bridge portions 12 may be disposed on two opposite sides of the first island portion 11 in the first direction (e.g., x direction or −x direction), and the remaining two first bridge portions 12 may be disposed on two opposite sides of the first island portion 11 in the second direction (e.g., y direction or −y direction). Four first bridge portions 12 may be respectively connected to four sides of the first island portion 11. Four first bridge portions 12 may be respectively adjacent to the corners of the first island portion 11.

In the non-display area, for example, the first non-display area NDA1 shown in FIG. 4A, the display panel 10 may include second island portions 21 apart from each other in the first direction (e.g., x direction or −x direction) and the second direction (e.g., y direction or −y direction), and second bridge portions 22 connecting adjacent second island portions 21.

The second bridge portions 22 may be apart from each other by a second opening CS2 located between the second bridge portions 22. The second bridge portion 22 may have a serpentine shape. In an embodiment, for example, as shown in FIG. 4C, the second bridge portion 22 may have an approximate ‘letter S’ shape. The size and/or width of the second bridge portion 22 may be different from the size and/or width of the first bridge portion 12. In an embodiment, for example, the size and/or width of the second bridge portion 22 may be greater than the size and/or width of the first bridge portion 12. The curvature radius of a round portion of the second bridge portion 22 may be different from the curvature radius of a round portion of the first bridge portion 12. In an embodiment, for example, the curvature radius of a round portion of the second bridge portion 22 may be greater than the curvature radius of a round portion of the first bridge portion 12.

Each second island portion 21 may be connected to a plurality of second bridge portions 22. Each second island portion 21 may be connected to four second bridge portions 22. Two second bridge portions 12 may be disposed on two opposite sides of the second island portion 21 in the first direction (e.g., x direction or −x direction), and the remaining two second bridge portions 22 may be disposed on two opposite sides of the second island portion 21 in the second direction (e.g., y direction or −y direction). In an embodiment, four second bridge portions 22 may be respectively connected to four sides of the second island portion 21. Each second bridge portion 22 may be connected to the central portion of each side of the second island portion 21.

The second island portions 21 in one of rows disposed in the first non-display area NDA1 may correspond to the first island portions 11 in a plurality of rows arranged in the display area DA. In an embodiment, for example, the second island portions 21 in one of rows disposed in the first non-display area NDA1 may correspond to first island portions 11 arranged in an i-th row in the display area DA, and first island portions 11 arranged in an (i+1)-th row in the display area DA (here, i is a positive integer greater than 0). In another embodiment, the second island portions 21 in one of rows may correspond to n rows of first island portions 11 (here, n is a positive integer equal to or greater than 3).

The non-display area, for example, the first non-display area NDA1 may include a first sub-non-display area SNDA1 in which the second island portions 21 and the second bridge portions 22 are disposed, and a second sub-non-display area SNDA2 between the first sub-non-display area SNDA1 and the display area DA. Third bridge portions 23 may be disposed in the second sub-non-display area SNDA2, where the third bridge portions 23 connect the display area DA to the first sub-non-display area SNDA1. One end of the third bridge portion 23 may be connected to the second island portion 21, and the other end of the third bridge portion 23 may be connected to the first island portion 11. In an embodiment, for example, one end of the third bridge portion 23 may be connected to the central portion of one side of the second island portion 21, and the other end of the third bridge portion 23 may be connected to the central portion of one side of the first island portion 11.

The third bridge portion 23 may have a serpentine shape. In an embodiment, the shape of the third bridge portion 23 may be different from the shape of each of the first bridge portion 12 and the second bridge portion 22. The width of the third bridge portion 23 may be different from the width of the first bridge portion 12 and the width of the second bridge portion 22. The width of the third bridge portion 23 may be greater than the width of the first bridge portion 12 and less than the width of the second bridge portion 22. Between the third bridge portions 23 in the second direction (e.g., y direction or −y direction), the third opening CS3 and the fourth opening CS4 having different shapes may be alternately disposed.

FIG. 4B is an enlarged plan view of a portion of the display panel 10, showing the display area DA of FIG. 3B according to an embodiment of the invention.

Referring to FIG. 4B, in an embodiment, the display panel 10 may include first island portions 11 and first bridge portions 12 connecting adjacent first island portions 11, where the first island portions 11 are apart from each other in the first direction (e.g., x direction or −x direction) and the second direction (e.g., y direction or −y direction) in the display area DA. The first bridge portions 12 may be apart from each other by a first opening CS1 located between the first bridge portions 12.

In an embodiment, at least one of sides of the first island portion 11 may be oblique with respect to an imaginary line connecting centers C of the first island portions 11 in the first direction (e.g., x direction or −x direction) and/or the second direction (e.g., y direction or −y direction). In an embodiment, as shown in FIG. 4B, the first island portion 11 includes first to fourth sides 11a, 11b, 11c, and 11d, and the first to fourth sides 11a, 11b, 11c, and 11d extend in a direction oblique with respect to a first imaginary line IM1 connecting the centers C of the island portions 11. Although FIG. 4B shows an embodiment where the first imaginary line IM1 extends in the first direction (e.g., x direction or −x direction), the first imaginary line IM1 may extend in the second direction (e.g., y direction or −y direction).

In an embodiment, the first side 11a and the third side 11c parallel to each other may cross the first imaginary line IM1. A small angle φ (hereinafter, referred to as an minor angle) among angles formed by the first side 11a and the first imaginary line IM1 may be greater than about 0° and less than about 90°. The minor angle φ between the third side 11c and the first imaginary line IM1 may be greater than about 0° and less than about 90°.

The first island portion 11 may be connected to a plurality of first bridge portions 12. In an embodiment, for example, the first island portion 11 may be connected to four first bridge portions 12. Two first bridge portions 12 may be disposed on two opposite sides of the first island portion 11 in the first direction (e.g., x direction or −x direction), and the remaining two first bridge portions 12 may be disposed on two opposite sides of the first island portion 11 in the second direction (e.g., y direction or −y direction).

The first bridge portion 12 may have a serpentine shape. In an embodiment, for example, as shown in FIG. 4B, the first bridge portion 12 may have a shape of an approximate ‘letter S’ (or S-like shape) such as including two curved portions 12R and a straight portion 12S between the two curved portions 12R.

In an embodiment, as shown in FIG. 4B, the straight portion 12S may be substantially parallel to a side of an adjacent first island portion 11. In an embodiment, for example, the straight portion 12S of each of the first bridge portions 12 located on two opposite sides of the first island portion 11 in the first direction (e.g., x direction or −x direction) may be substantially parallel to a side (e.g., the first side 11a and the third side 11c) of the first island portion 11. The straight portion 12S of each of the first bridge portions 12 located on two opposite sides of the first island portion 11 in the second direction (e.g., y direction or −y direction) may be substantially parallel to a side (e.g., the second side 11b and the fourth side 11d) of the first island portion 11.

Each of the first island portions 11 shown in FIG. 4B may be understood as each of the first island portions 11 shown in FIG. 4A being rotated by a first angle (e.g., an acute angle) with respect to the center C. Accordingly, at least one of sides of the first island portion 11 may be oblique with respect to an imaginary line connecting the centers C of the first island portions 11 in the first direction (e.g., x direction or −x direction) and/or the second direction (e.g., y direction or −y direction). Depending on the arrangement of the first island portions 11 and/or the structure of the first bridge portion 12, the area of the first opening CS1 shown in FIG. 4B may be relatively less than the area of the first opening CS1 shown in FIG. 4A, and accordingly, the display panel 10 according to the embodiment shown in FIG. 4B may provide relatively high-resolution images.

Although FIG. 4B shows an embodiment where the straight portion 12S of the first bridge portion 12 is substantially parallel to a side of the first island portion 11 adjacent to the straight portion 12S when the display panel 10 is stretched, the invention is not limited thereto. In another embodiment, the straight portion 12S of the first bridge portion 12 may be oblique to a side of a first island portion 11 adjacent to the straight portion 12S as shown in FIG. 4A.

In an embodiment, the structure of the first non-display area NDA1 (FIG. 3) of the display panel 10 not disclosed in FIG. 4B may be the same as the structure of the display area DA disclosed in FIG. 4B. In an embodiment, the structure of the first non-display area NDA1 (FIG. 3) of the display panel 10 not disclosed in FIG. 4B may be substantially the same as the structure of the display area DA disclosed in FIG. 4D, and the area of the second island portion disposed in the first non-display area NDA1 (FIG. 3) may be greater than the area of the first island portion 11. In such an embodiment, one second island portion may correspond to the plurality of first island portions 11 arranged in adjacent rows as described with reference to FIG. 4A.

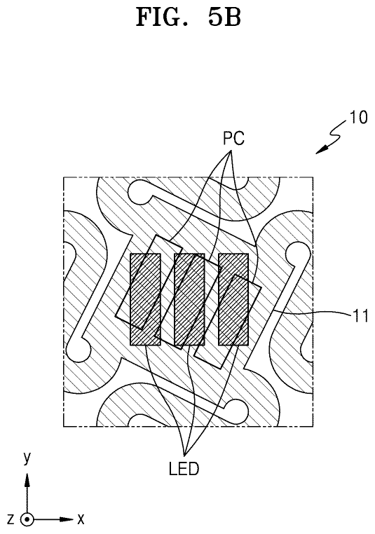

FIGS. 5A and 5B are respectively schematic cross-sectional views of the first island portion 11 and the first bridge portion 12 disposed in the display area DA of the display panel 10 according to an embodiment of the invention.

Referring to FIGS. 5A and 5B, in an embodiment, the first island portion 11 may include a light-emitting element LED and a pixel driving circuit portion PC. The light-emitting element LED and the pixel driving circuit portion PC of each first island portion 11 may be provided in plurality. In an embodiment, as shown in FIG. 5A, the arrangement direction of the pixel driving circuit portions PC and the arrangement direction of the light-emitting elements LED may be the same direction (e.g., x direction or −x direction). In another embodiment, as shown in FIG. 5B, the arrangement direction (e.g., x direction or −x direction) of the pixel driving circuit portions PC and the arrangement direction of the light-emitting elements LED may cross each other to have an acute angle. In such an embodiment, the arrangement direction of the light-emitting elements LED may be oblique with respect to the arrangement direction (e.g., x direction or −x direction) of the pixel driving circuit portions PC.

In an embodiment, although FIGS. 5A and 5B show embodiments where three pixel driving circuit portions PC are disposed in each first island portion 11, and three light-emitting elements LED are respectively connected to the pixel driving circuit portions PC, the invention is not limited thereto. In another embodiment, the number of pixel driving circuit portions PC and the number of light-emitting elements LED disposed in the first island portion 11 may be one, two, or four or more.

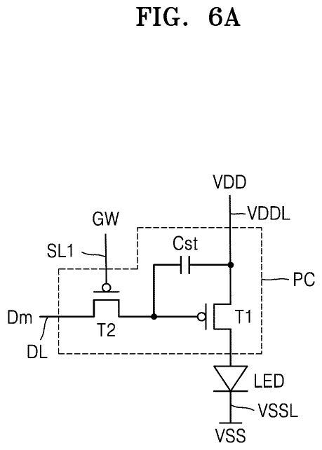

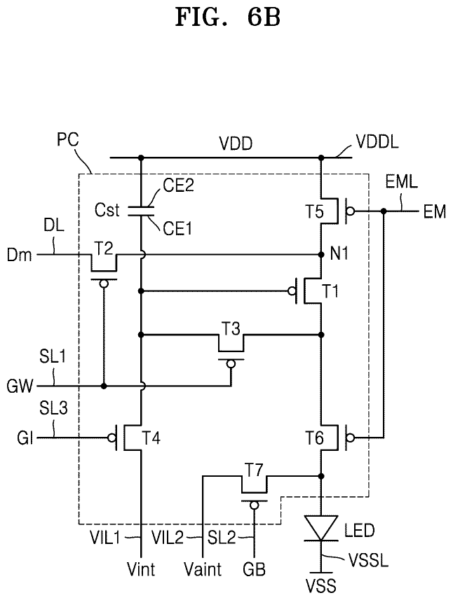

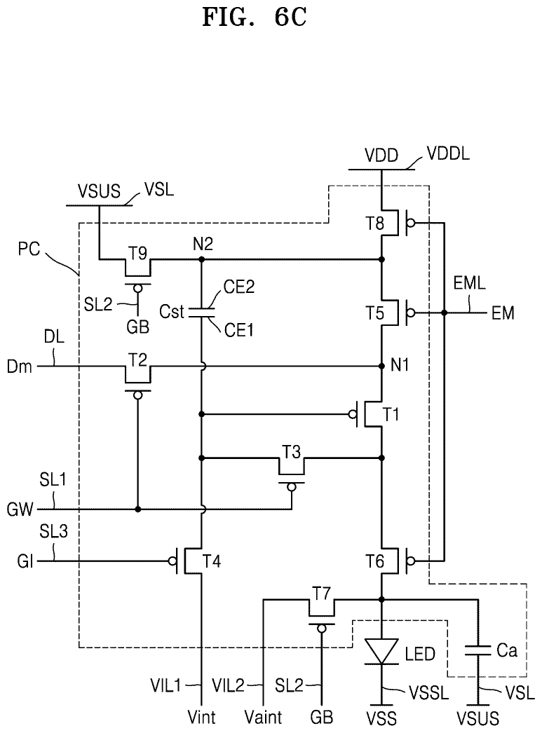

FIGS. 6A to 6C are equivalent circuit diagrams of a sub-pixel of the display panel 10 (FIGS. 5A and 5B) according to an embodiment of the invention.

Referring to FIG. 6A, in an embodiment, the light-emitting element LED corresponding to a sub-pixel may be electrically connected to the pixel driving circuit portion PC, and the pixel driving circuit portion PC may include a first transistor T1, a second transistor T2, and a storage capacitor Cst. The pixel driving circuit portion PC may be electrically connected to a signal line and a voltage line. The signal line may include a gate line such as a first scan line SL1, and a data line DL, and the voltage line may include a first voltage line VDDL.

The second transistor T2 may be electrically connected to the first scan line SL1 and the data line DL. The first scan line SL1 may provide a first scan signal GW to a gate electrode of the second transistor T2. The second transistor T2 may transfer a data signal Dm to the first transistor T1 in response to a first scan signal GW input from the first scan line GL1, where the data signal Dm is input from the data line DL.

The storage capacitor Cst may be electrically connected to the second transistor T2 and the first voltage line VDDL and may store a voltage corresponding to a difference between a voltage transferred from the second transistor T2 and a first power voltage VDD supplied by the first voltage line VDDL.

The first transistor T1 is a driving transistor and may control a driving current flowing through the light-emitting element LED. The first transistor T1 may be connected to the first voltage line VDDL and the storage capacitor Cst. The first transistor T1 may control the driving current flowing from the first voltage line VDDL to the light-emitting element LED based on a voltage value stored in the storage capacitor Cst. The light-emitting element LED may emit light having a preset brightness corresponding to the driving current. A first electrode of the light-emitting element LED may be electrically connected to the first transistor T1, and a second electrode may be electrically connected to a second voltage line VSSL supplying a second power voltage VSS.

Although FIG. 6A shows an embodiment where the pixel driving circuit portion PC includes two transistors and one storage capacitor, the pixel driving circuit portion PC may include three or more transistors in another embodiment.

Referring to FIG. 6B, in another embodiment, the pixel driving circuit portion PC may include the first transistor T1, the second transistor T2, a third transistor T3, a fourth transistor T4, a fifth transistor T5, a sixth transistor T6, a seventh transistor T7, and the storage capacitor Cst.

The pixel driving circuit portion PC is electrically connected to signal lines and voltage lines. The signal lines may include a gate line such as the first scan line SL1, a second scan line SL2, a third scan line SL3, and an emission control line EML, and the data line DL. The voltage lines may include first and second initialization voltage lines VIL1 and VIL2, and the first voltage line VDDL.

The first voltage line VDDL may transfer the first power voltage VDD to the first transistor T1. The first initialization voltage line VIL1 may transfer a first initialization voltage Vint to the pixel driving circuit portion PC, where the first initialization voltage Vint initializes the first transistor T1. The second initialization voltage line VIL2 may transfer a second initialization voltage Vaint to the pixel driving circuit portion PC, where the second initialization voltage Vaint initializes the first electrode of the light-emitting element LED.

The first transistor T1 may be connected to the first voltage line VDDL through the fifth transistor T5 and electrically connected to the light-emitting element LED through the sixth transistor T6. The first transistor T1 is a driving transistor, and receives a data signal Dm and supplies the driving current to the light-emitting element LED based on a switching operation of the second transistor T2.

The second transistor T2 is a data-write transistor and is electrically connected to the first scan line SL1 and the data line DL. The second transistor T2 is electrically connected to the first voltage line VDDL through the fifth transistor T5. The second transistor T2 is turned on in response to a first scan signal GW transferred through the first scan line SL1, and performs a switching operation of transferring a data signal Dm to a first node N1, where the data signal Dm is transferred through the data line DL.

The third transistor T3 is electrically connected to the first scan line SL1 and electrically connected to the light-emitting element LED through the sixth transistor T6. The third transistor T3 may be turned on in response to a first scan signal GW to diode-connect the first transistor T1, where the first scan signal GW is transferred through the first scan line SL1.

The fourth transistor T4 is a first initialization transistor and is electrically connected to the third scan line SL3 and the first initialization voltage line VIL1. The fourth transistor T4 may be turned on in response to a third scan signal GI to initialize a voltage of the gate electrode of the first transistor T1 by transferring the first initialization voltage Vint to the gate electrode of the first transistor T1, where the first initialization voltage Vint is from the first initialization voltage line VIL1, and the third scan signal GI is transferred through the third scan line SL3. The third scan signal GI may correspond to a first scan signal of another pixel driving circuit portion disposed in a previous row of the relevant pixel driving circuit portion PC.

The fifth transistor T5 may be an operation control transistor, and the sixth transistor T6 may be an emission control transistor. The fifth transistor T5 and the sixth transistor T6 may be electrically connected to the emission control line EML, simultaneously turned on in response to an emission control signal EM transferred through the emission control line EML, and may form a current path such that the driving current flows in a direction from the first voltage line VDDL to the light-emitting element LED.

The seventh transistor T7 is a second initialization transistor and may be electrically connected to the second scan line SL2, the second initialization voltage line VIL2, and the sixth transistor T6. The seventh transistor T7 is turned on in response to a second scan signal GB transferred through the second scan line SL2, and may transfer the second initialization voltage Vaint from the second initialization voltage line VIL2 to the first electrode of the light-emitting element LED, thereby initializing the first electrode of the light-emitting element LED.

The storage capacitor Cst includes a first electrode CE1 and a second electrode CE2. The first electrode CE1 is electrically connected to the gate electrode of the first transistor T1, and the second electrode CE2 is electrically connected to the first voltage line VDDL. The storage capacitor Cst may maintain a voltage applied to the gate electrode of the first transistor T1 by storing and maintaining a voltage corresponding to a difference between voltages of two opposite ends of the gate electrode of the first transistor T1 and the first voltage line VDDL.

Referring to FIG. 6C, in another embodiment, the pixel driving circuit portion PC may include the first transistor T1, the second transistor T2, the third transistor T3, the fourth transistor T4, the fifth transistor T5, the sixth transistor T6, the seventh transistor T7, an eighth transistor T8, a ninth transistor T9, the storage capacitor Cst, and an auxiliary capacitor Ca.

The pixel driving circuit portion PC is electrically connected to signal lines and voltage lines. The signal lines may include a gate line such as the first scan line SL1, the second scan line SL2, the third scan line SL3, and the emission control line EML, and the data line DL. The voltage lines may include the first and second initialization voltage lines VIL1 and VIL2, a sustain voltage line VSL, and the first voltage line VDDL.

The first voltage line VDDL may transfer the first power voltage VDD to the first transistor T1. The first initialization voltage line VIL1 may transfer the first initialization voltage Vint to the pixel driving circuit portion PC, where the first initialization voltage Vint initializes the first transistor T1. The second initialization voltage line VIL2 may transfer the second initialization voltage Vaint to the pixel driving circuit portion PC, where the second initialization voltage Vaint initializes the first electrode of the light-emitting element LED. The sustain voltage line VSL may provide a sustain voltage VSUS to a second node N2, for example, the second electrode CE2 of the storage capacitor Cst during an initialization section and a data-write section.

The first transistor T1 may be electrically connected to the first voltage line VDDL through the fifth transistor T5 and the eighth transistor T8 and electrically connected to the light-emitting element LED through the sixth transistor T6. The first transistor T1 serves as a driving transistor, and may receive a data signal Dm and supply the driving current to the light-emitting element LED based on a switching operation of the second transistor T2.

The second transistor T2 is electrically connected to the first scan line SL1 and the data line DL and electrically connected to the first voltage line VDDL through the fifth transistor T5 and the eighth transistor T8. The second transistor T2 may be turned on in response to a first scan signal GW transferred through the first scan line SL1 and may perform a switching operation of transferring a data signal Dm to the first node N1, where the data signal Dm is transferred through the data line DL.

The third transistor T3 is electrically connected to the first scan line SL1 and electrically connected to the light-emitting element LED through the sixth transistor T6. The third transistor T3 may be turned on in response to a first scan signal GW to compensate for a threshold voltage of the first transistor T1 by diode-connecting the first transistor T1, where the first scan signal GW is transferred through the first scan line SL1.

The fourth transistor T4 is electrically connected to the third scan line SL3 and the first initialization voltage line VIL1, turned on in response to a third scan signal GI transferred through the third scan line SL3, and initializes a voltage of the gate electrode of the first transistor T1 by transferring the first initialization voltage Vint from the first initialization voltage line VIL1 to the gate electrode of the first transistor T1. The third scan signal GI may correspond to a first scan signal of another pixel driving circuit portion disposed in a previous row of the relevant pixel driving circuit portion PC.

The fifth transistor T5, the sixth transistor T6, and the eighth transistor T8 may be electrically connected to the emission control line EML, simultaneously turned on in response to an emission control signal EM transferred through the emission control line EML, and may form a current path such that the driving current flows in a direction from the first voltage line VDDL to the light-emitting element LED.

The seventh transistor T7 is a second initialization transistor and may be electrically connected to the second scan line SL2, the second initialization voltage line VIL2, and the sixth transistor T6. The seventh transistor T7 is turned on in response to a second scan signal GB transferred through the second scan line SL2, and transfers the second initialization voltage Vaint from the second initialization voltage line VIL2 to the first electrode of the light-emitting element LED, thereby initializing the first electrode of the light-emitting element LED.

The ninth transistor T9 may be electrically connected to the second scan line SL2, the second electrode CE2 of the storage capacitor Cst, and the sustain voltage line VSL. The ninth transistor T9 is turned on in response to a second scan signal GB transferred through the second scan line SL2 and may transfer the sustain voltage VSUS to the second node N2, for example, the second electrode CE2 of the storage capacitor Cst during the initialization section and the data-write section.

Each of the eighth transistor T8 and the ninth transistor T9 may be electrically connected to the second node N2, for example, the second electrode CE2 of the storage capacitor Cst. In an embodiment, during the initialization section and the data-write section, the eighth transistor T8 may be turned off and the ninth transistor T9 may be turned on. During an emission section, the eighth transistor T8 may be turned on and the ninth transistor T9 may be turned off. Because the sustain voltage VSUS is transferred to the second node N2 during the initialization section and the data-write section, uniformity (e.g., long range uniformity (LRU)) in brightness of the display device depending on a voltage drop of the first voltage line VDDL may be improved.

The storage capacitor Cst includes the first electrode CE1 and the second electrode CE2. The first electrode CE1 is electrically connected to the gate electrode of the first transistor T1, and the second electrode CE2 is electrically connected to the eighth transistor T8 and the ninth transistor T9.

The auxiliary capacitor Ca may be electrically connected to the sixth transistor T6, the sustain voltage line VSL, and the first electrode of the light-emitting element LED. The auxiliary capacitor Ca may effectively prevent a black brightness from rising when the sixth transistor T6 is turned off by storing and maintaining a voltage corresponding to a voltage difference between the first electrode of the light-emitting element LED and the sustain voltage line VSL while the seventh transistor T7 and the ninth transistor T9 are turned on.

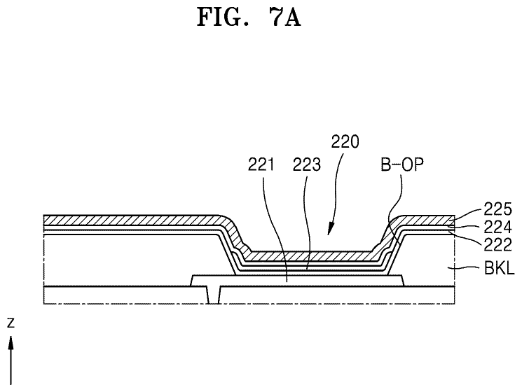

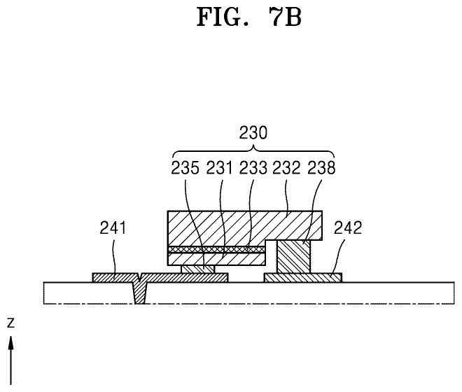

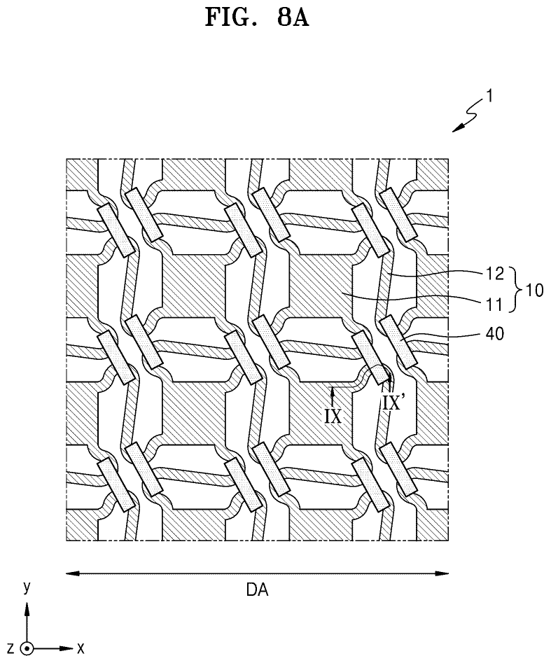

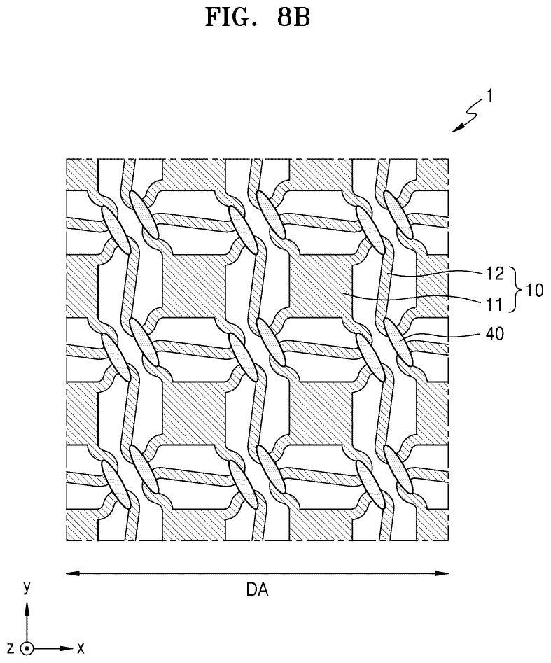

FIG. 7A is a schematic cross-sectional view of the light-emitting element LED (FIGS. 5A and 5B) of the display panel 10 (FIGS. 5A and 5B) according to an embodiment of the invention.

Referring to FIG. 7A, the light-emitting element LED (FIGS. 5A and 5B) according to an embodiment of the invention may include an organic light-emitting diode 220 including an organic material. The organic light-emitting diode 220 may include a first electrode 221 disposed on an insulating layer, a second electrode 225 facing the first electrode 221, and an emission layer 223 disposed between the first electrode 221 and the second electrode 225. A first functional layer 222 may be disposed between the first electrode 221 and the emission layer 223, and a second functional layer 224 may be disposed between the emission layer 223 and the second electrode 225.

The edge of the first electrode 221 may be covered by a bank layer BKL including an insulating material. The bank layer BKL may define or be provided with an opening B-OP overlapping the central portion of the first electrode 221.

The first electrode 221 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In another embodiment, the first electrode 221 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. In another embodiment, the first electrode 221 may further include a layer on/under the reflective layer, the layer including ITO, IZO, ZnO, AZO, or In₂O₃.

The emission layer 223 may include a polymer organic material or a low-molecular weight organic material emitting light having a preset color. The first functional layer 222 may include a hole transport layer (HTL) and/or a hole injection layer (HIL). The second functional layer 224 may include an electron transport layer (ETL) and/or an electron injection layer (EIL).

The second electrode 225 may include a conductive material having a low work function. In an embodiment, for example, the second electrode 225 may include a (semi) transparent layer including silver (Ag), magnesium (Mg), aluminum (Al), platinum (Pt), palladium (Pd), gold (Au), nickel (Ni), neodymium (Nd), iridium (Ir), chrome (Cr), or an alloy thereof. Alternatively, the second electrode 225 may further include a layer on the (semi) transparent layer, the layer including ITO, IZO, ZnO, AZO, or In₂O₃.

FIG. 7B is a schematic cross-sectional view of the light-emitting element LED (FIGS. 5A and 5B) of the display panel 10 (FIGS. 5A and 5B) according to an embodiment of the invention.

Referring to FIG. 7B, the light-emitting element LED (FIGS. 5A and 5B) according to an embodiment of the invention may include an inorganic light-emitting diode 230 including an inorganic material. The inorganic light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the inorganic light-emitting diode 230 may be respectively electrically connected to a first electrode pad 241 and a second electrode pad 242 disposed in (or directly on) a same layer as each other.

In an embodiment, the first semiconductor layer 231 may include a p-type semiconductor layer. The p-type semiconductor layer may be selected from among semiconductor materials having a composition formula of InₓAl_{y}Ga_{1-x-y}N (0≤x≤1, 0≤y≤1, 0≤x+y≤1), such as GaN, AlN, AlGaN, InGaN, InN, InAlGaN, AlInN, and the like, and may be doped with a p-type dopant such as Mg, Zn, Ca, Sr, or Ba.

The second semiconductor layer 232 may include, for example, an n-type semiconductor layer. The n-type semiconductor layer may be selected from among semiconductor materials having a composition formula of InₓAl_{y}Ga_{1-x-y}N (0≤x≤1, 0≤y≤1, 0≤x+y≤1), such as GaN, AlN, AlGaN, InGaN, InN, InAlGaN, AlInN, and the like, and may be doped with an n-type dopant such as Si, Ge, or Sn.

The intermediate layer 233 is a region in which electrons and holes recombine, and when electrons and holes recombine, they transition to a lower energy level and light having a corresponding wavelength may be created. The intermediate layer 233 may include, for example, a semiconductor material having a composition formula of InₓAl_{y}Ga_{1-x-y}N (0≤x≤1, 0≤y≤1, 0≤x+y≤1), and be formed in a single quantum-well structure or a multi quantum-well structure. In addition, the intermediate layer 233 may include a quantum-wire structure or a quantum-dot structure.

Although FIG. 7B shows an embodiment where the first semiconductor layer 231 includes a p-type semiconductor layer and the second semiconductor layer 232 includes an n-type semiconductor layer, the invention is not limited thereto. In another embodiment, the first semiconductor layer 231 may include an n-type semiconductor layer, and the second semiconductor layer 232 may include a p-type semiconductor layer.

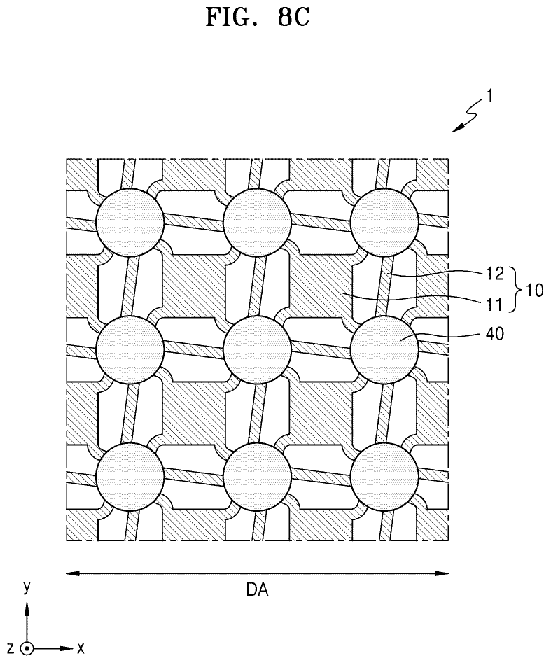

FIGS. 8A to 8C are respectively excerpted plan views of a portion of the display area DA of the display device 1 according to an embodiment of the invention.

Referring to FIGS. 8A to 8C, in an embodiment, the display device 1 may include force portions 40 apart from each other in a plan view (or when viewed in z direction). The force portions 40 may overlap the display panel 10 in the plan view. The force portions 40 may overlap at least two first bridge portions 12 in the plan view. In the disclosure, the force portions 40 may be elements that apply a force or a pressure to the first bridge portions 12 in the z direction, e.g., twist-resistive pressing elements. Here, z direction may be a thickness direction of the display panel. FIGS. 8A and 8B illustrate embodiments where each force portion 40 overlaps two adjacent first bridge portions 12 in the plan view, and FIG. 8C shows an embodiment where each force portion 40 overlaps four adjacent first bridge portions 12 in the plan view. Each force portion 40 may overlap the curved portion 12R of the relevant first bridge portion 12 in the plan view.

In the plan view, the force portion 40 may have a polygonal shape, an elliptical shape, or a circular shape. In an embodiment, in the plan view, the force portion 40 may have a polygonal shape such as having a quadrangular shape as shown in FIG. 8A. Although FIG. 8A shows an embodiment where the force portion 40 has a quadrangular shape, the invention is not limited thereto. The force portion may have a polygonal shape of various structures, such as a triangle, pentagon, hexagon, heptagon, or octagon. In an embodiment, for example, in the plan view, the force portion 40 may have an elliptical shape as shown in FIG. 8B. In an embodiment, for example, in the plan view, the force portion 40 may have a circular shape as shown in FIG. 8C.

Although FIGS. 8A and 8B show embodiments where the force portions 40 extend in a same direction as each other, the invention is not limited thereto. In another embodiment, an extension direction of each of the force portions 40 in an n-th row (n is a positive integer) and an extension direction of each of the force portions 40 in an (n−1)-th row arranged in the first direction (x direction or −x direction) may be different from each other.

FIGS. 9A and 9B are respectively cross-sectional views of a portion of the display area DA of a display device 1 according to an embodiment of the invention. FIGS. 9A and 9B are cross-sections taken along line IX-IX′ of FIG. 8 and show one (e.g., first force portion 40) of the force portions 40 shown in FIG. 8. Characteristics of one (e.g., first force portion 40) of the force portions 40 to be described with reference to FIGS. 9A and 9B are the same as characteristics of other force portions 40 shown in FIG. 8.

In an embodiment, the display device 1 may include the force portion 40 disposed on the display panel 10 and overlapping the first bridge portion 12. An upper protective layer 30 (or first protective layer) may be disposed over the first surface (e.g., the upper surface) of the display panel 10, and the force portion 40 may be disposed between the first surface (e.g., the upper surface) of the display panel 10 and the upper protective layer 30. In an embodiment, a first adhesive layer 20 may be disposed between the force portion 40 and the upper protective layer 30. The force portion 40, the first adhesive layer 20, and the upper protective layer 30 may correspond to the upper layer 70 described above with reference to FIG. 3A.

A lower protective layer 60 (or second protective layer) may be disposed over the second surface (e.g., lower surface) which is the opposite side to the first surface (e.g., upper surface) of the display panel 10. In an embodiment, a second adhesive layer 50 may be disposed between the second surface (e.g., lower surface) of the display panel 10 and the lower protective layer 60. The second adhesive layer 50 and the lower protective layer 60 may correspond to the lower layer 80 described above with reference to FIG. 3A.

The upper protective layer 30 and/or the lower protective layer 60 may include an elastomeric polymer. The upper protective layer 30 and/or the lower protective layer 60 may include at least one selected from thermoplastic polyurethane, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, polydimethylsiloxane (PDMS), and ecoflex. The upper protective layer 30 and the lower protective layer 60 may include a same material as each other and different materials from each other.

The force portion 40 may be disposed between the first adhesive layer 20 and the display panel 10, and a first surface (e.g., surface facing the display panel 10, lower surface in FIGS. 9A and 9B) of the force portion 40 may be in contact with the display panel 10 but is not fixed to the display panel 10. While the display device 1 is stretched, the first surface (e.g., lower surface) of the force portion 40 may be in contact with the first surface (e.g., surface facing the force portion 40, upper surface in FIGS. 9A and 9B) of the display panel 10 and may move with respect to the first surface in a sliding manner. While the display device 1 is stretched, a shape (e.g., shape of the first opening CS1 described with reference to FIGS. 4A and 4B) between the first bridge portions 12 of the display panel 10 is transformed and a distance between the first island portions 11 may increase. While the display device 1 is stretched, the first bridge portions 12 may be twisted and transformed, and an issue may occur in which stresses are concentrated on the curved portions 12R (see FIGS. 4A and 4B) and the curved portions 12R (see FIGS. 4A and 4B) are disconnected. In an embodiment of the invention, because the force portion 40 exerts force to the first bridge portion 12 (e.g., curved portion 12R (see FIGS. 4A and 4B) of the first bridge portion 12), the above issue may be effectively prevented or substantially minimized. In the specification, stretching of the display device 1 may mean stretching of the display panel 10. Accordingly, in the specification, “stretching of the display device 1” may be understood as “stretching of the display panel 10”.

A modulus (or Young's modulus) of the force portion 40 may be greater than a modulus (or Young's modulus) of the first bridge portion 12 of the display panel 10. In an embodiment, for example, a modulus M of the force portion 40 may be greater than about 27 MPa and equal to or less than about 12 GPa (i.e., 27 Mpa<M≤12 GPa).

The force portion 40 may include a first polymer material. In an embodiment, for example, the first polymer material of the force portion 40 may include a polymer cured by heat or light. In an embodiment, the force portion 40 may include a polymer cured by an ultraviolet ray (UV). The force portion 40 may include various types of first polymers, such as polymethyl methacrylate (PMMA), acryl-based materials, or epoxy-based materials.

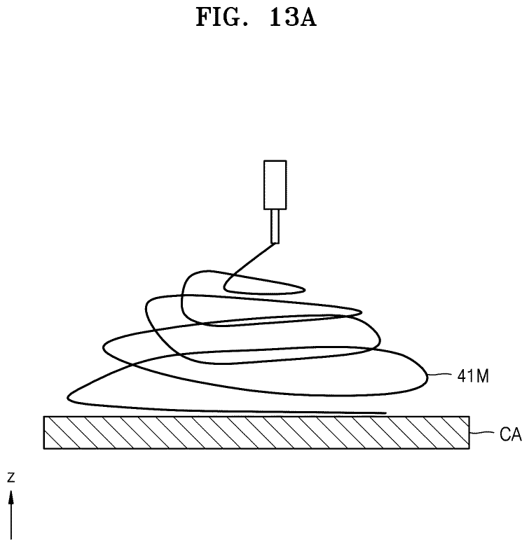

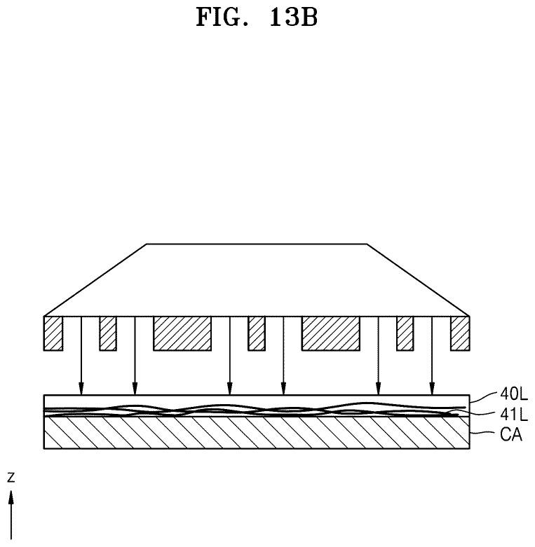

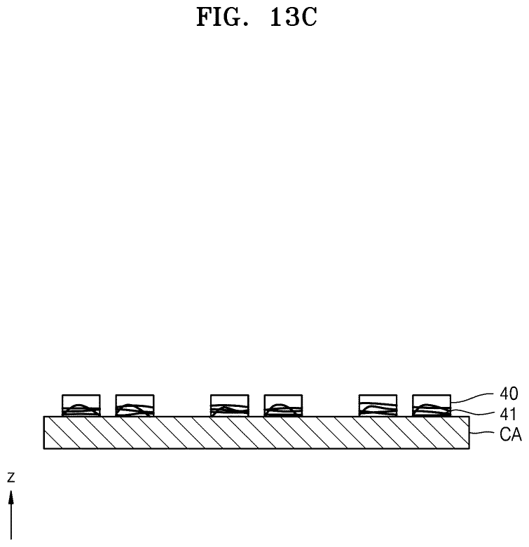

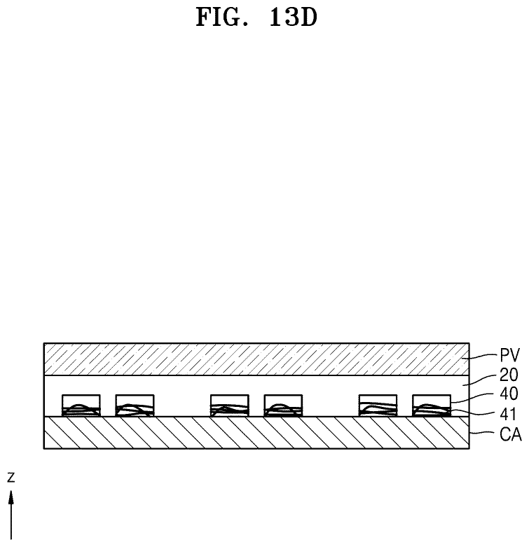

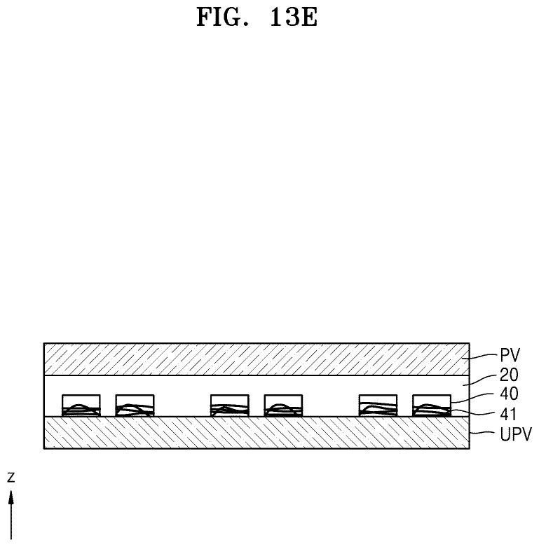

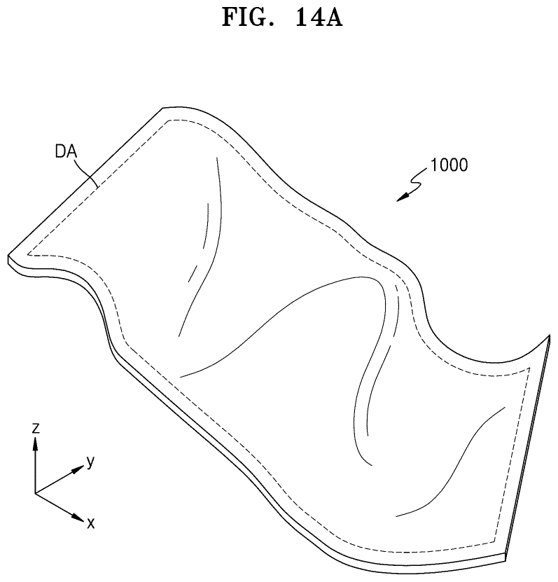

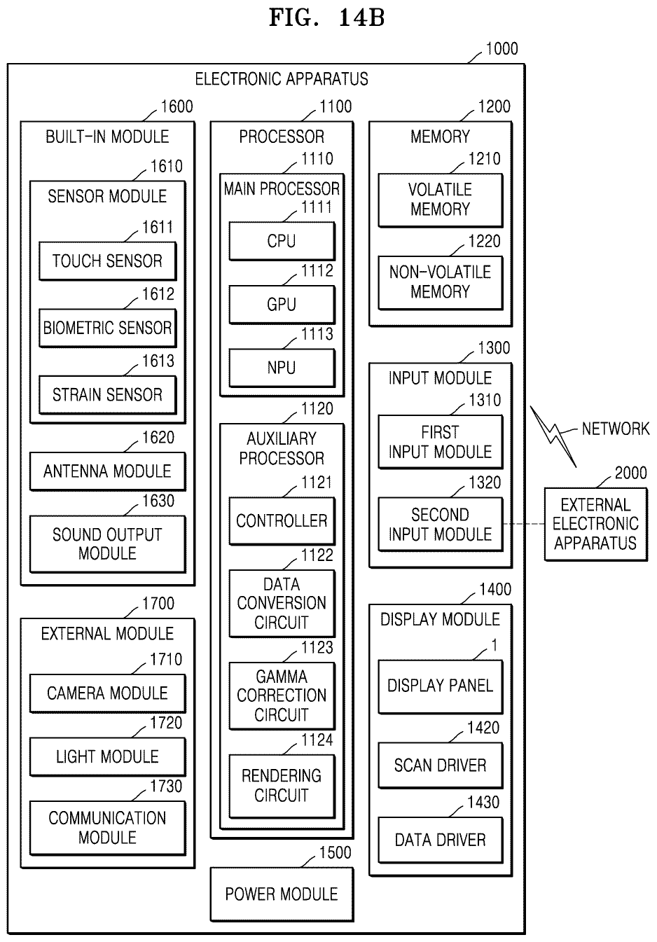

In an embodiment, the force portion 40 may further include a second polymer material. The second polymer material is a different type of material from the first polymer material, and the second polymer material may have a function that makes it easy to separate the force portion 40 from a carrier substrate during the manufacturing process of the force portion 40. The second polymer material may include a polymer whose adhesiveness may be changed by heat or light. In an embodiment, the second polymer material may include a thermo-responsive polymer, such as polycaprolactone (PCL). The force portion 40 including the second polymer material will be described later in greater detail with reference to FIGS. 13A to 13E.

The first adhesive layer 20 and/or second adhesive layer 50 may include a polymer resin. In an embodiment, for example, the first adhesive layer 20 and/or second adhesive layer 50 may include pressure sensitive adhesive (PSA), optical clear adhesive (OCA), or optical clear resin (OCR).

In an embodiment, the force portion 40 may be disposed on one surface of the first adhesive layer 20 facing the display panel 10 as shown in FIG. 9A. In an embodiment, as shown in FIG. 9A, a preset gap (or cavity) may be between one surface of the first adhesive layer 20 and the display panel 10 around the force portion 40. In an embodiment, as shown in FIG. 9B, the force portion 40 may be disposed or embedded in the first adhesive layer 20. In such an embodiment, the material corresponding to the first adhesive layer 20 may be in direct contact with the surfaces other than the first surface (e.g., the lower surface) of the force portion 40, such as the lateral surface of the force portion 40 and the second surface (e.g., upper surface) of the force portion 40. The thickness of a portion of the first adhesive layer 20 overlapping the force portion 40 in the z direction may be less than the thickness of a portion of the first adhesive layer 20 not overlapping the force portion 40 in the z direction.

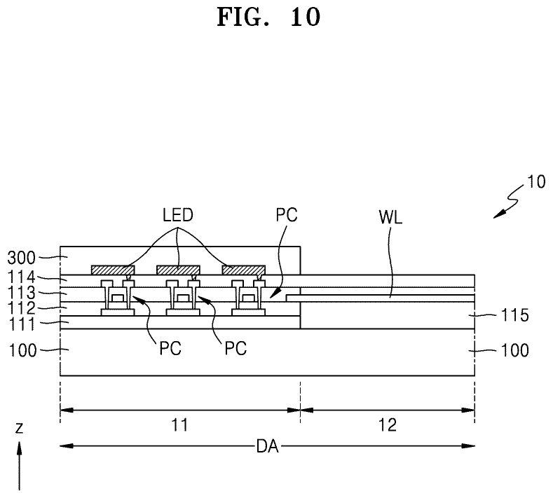

FIG. 10 is a cross-sectional view of a portion of the display panel 10 according to an embodiment of the invention.

Referring to FIG. 10, in an embodiment, the first island portion 11 may include the light-emitting elements LED and a circuit, for example, the pixel driving circuit portion PC electrically connected thereto and driving the light-emitting elements. The first bridge portion 12 may include a wiring WL electrically connected to the pixel driving circuit portions PC respectively disposed in adjacent first island portions 11.

In the first island portion 11, a buffer layer 111 including an inorganic insulating material may be disposed on the substrate 100, and the pixel driving circuit portion PC may be disposed on the buffer layer 111. Insulating layers including an inorganic insulating material and/or an organic insulating material may be disposed between the pixel driving circuit portion PC and the light-emitting element LED. In an embodiment, for example, a gate insulating layer 112 may be disposed between a semiconductor layer and a gate electrode of a transistor of the pixel driving circuit portion PC, and an interlayer insulating layer 113 may be disposed between the gate electrode and a source electrode, and/or the gate electrode and a drain electrode. The buffer layer 111, the gate insulating layer 112, and the interlayer insulating layer 113 may include an inorganic insulating material. A planarization layer 114 may be disposed between the pixel driving circuit portion PC and the light-emitting element LED. The planarization layer 114 may include an organic insulating material.

The light-emitting element LED may be disposed on the planarization layer 114 and electrically connected to the pixel driving circuit portion PC corresponding thereto. The light-emitting elements LED may emit light of different colors or light of a same color. In an embodiment, the light-emitting elements LED may emit red, green, and blue light. In an embodiment, the light-emitting elements LED may emit white light. In another embodiment, the light-emitting elements LED may emit red, green, blue light, and white light.

The substrate 100 may include polymer resin such as polyethersulfone, polyarylate, polyetherimide, polyethylene naphthalate, polyethylene terephthalate, polyphenylene sulfide, polyimide, polycarbonate, cellulose triacetate, cellulose acetate propionate, and the like. In an embodiment, the substrate 100 may be a single layer including the polymer resin. In another embodiment, the substrate 100 may have a multi-layered structure including a base layer and a barrier layer, where the base layer includes the polymer resin and the barrier layer includes an inorganic insulating material. The substrate 100 including the polymer resin may be flexible, rollable, or bendable.

In an embodiment, the substrate 100 may include a region corresponding to the first island portion 11 and a region corresponding to the first bridge portion 12. In such an embodiment, the planar shape of the display panel 10 described with reference to FIGS. 4A and 4B may be the same as the shape of the substrate 100. In an embodiment, for example, the substrate 100 may be provided with an opening area corresponding to the first opening CS1 described with reference to FIGS. 4A and 4B. Like the structure described with reference to FIG. 4A, the substrate 100 may include a region corresponding to the first island portion 11, a region corresponding to the first bridge portion 12, a region corresponding to the second island portion 21, a region corresponding to the second bridge portion 22, an opening area corresponding to the first opening CS1, and an opening area corresponding to the second opening CS2. The planar shape of the display panel 10 shown in FIGS. 4A and 4B is substantially the same as the planar shape of the substrate 100.

Although FIG. 10 shows an embodiment where three pixel driving circuit portions PC are disposed in each first island portion 11, and three light-emitting elements LED are respectively connected to the pixel driving circuit portions PC, the invention is not limited thereto. In another embodiment, the number of pixel driving circuit portions PC and the number of light-emitting elements LED disposed in the first island portion 11 may be one, two, or four or more.

An encapsulation layer 300 may be disposed on the light-emitting element LED, may fix the position of the light-emitting element LED, and protect the light-emitting element LED from external foreign substances. In another embodiment, the encapsulation layer 300 may include an organic material such as resin. In an embodiment, the encapsulation layer 300 may include urethane epoxy acrylate. The encapsulation layer 300 may include a photosensitive material, for example, a material such as a photoresist.

In an embodiment, the encapsulation layer 300 may include an inorganic encapsulation layer and/or an organic encapsulation layer. In an embodiment, the encapsulation layer 300 may include a structure in which an inorganic encapsulation layer including an inorganic insulating material, an organic encapsulation layer including an organic insulating material, and an inorganic encapsulation layer including an inorganic insulating material are stacked.

In the first bridge portion 12, an auxiliary insulating layer 115 including an organic insulating material may be disposed on the substrate 100. Inorganic insulating layers, for example, the buffer layer 111, the gate insulating layer 112, and the interlayer insulating layer 113 disposed in the first island portion 11 may not extend to the first bridge portion 12. The auxiliary insulating layer 115 may cover a step difference of each of the inorganic insulating layers, for example, the buffer layer 111, the gate insulating layer 112, and the interlayer insulating layer 113, and support the wiring WL. The planarization layer 114, which is an organic insulation layer, may extend to the first bridge portion 12 and protect the upper portion of the wiring WL. The encapsulation layer 300 may not extend to the first bridge portion 12.

As described above, the wirings WL of the first bridge portion 12 may be signal lines (e.g., a gate line, a data line, and the like) for providing electrical signals, or voltage lines (e.g., a driving voltage line, an initialization voltage line, and the like) for proving voltages to transistors included in the pixel driving circuit portion PC of the first island portion 11.

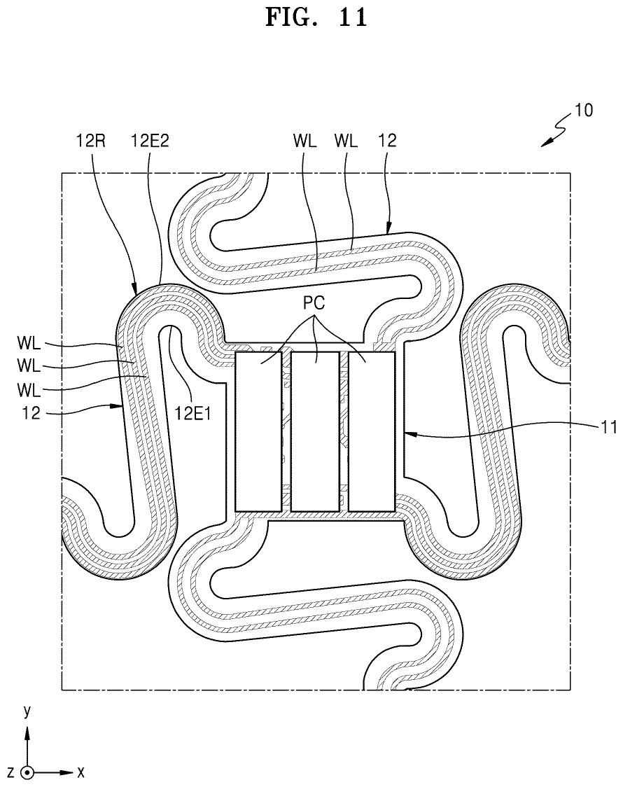

FIG. 11 is a plan view of the pixel driving circuit portion PC and the wiring WL of the display panel 10 according to an embodiment of the invention.

Referring to FIG. 11, in an embodiment, the wirings WL electrically connected to the pixel driving circuit portions PC in the first island portion 11 may pass or extend through the first bridge portions 12 connected to the first island portion 11. The wirings WL passing through one of the first bridge portions 12 may electrically connect the pixel driving circuit portions PC in two adjacent first island portions 11.

The wirings WL may be the signal lines (e.g., gate line, data line, and the like) for providing electrical signal, or the voltage lines (e.g., driving voltage line, initialization voltage line, and the like) for providing voltages to the transistor included in the pixel driving circuit portion PC.

In an embodiment where the first bridge portion 12 includes the curved portion as shown in FIG. 11, the wirings WL may be disposed offset toward an outer edge 12E2 with a relatively large radius of curvature among the edges 12E1 and 12E2 on two opposite sides of the curved portion 12R of the first bridge portion 12. Because the inner edge 12E1 of the curved portion 12R with a relatively small radius of curvature is more stressed than the outer edge 12E2, damage to the wiring WL may be prevented through the arrangement of the wiring WL described above.

Referring to FIGS. 8A, 8B, 8C, and 11, the force portion 40 (FIGS. 8A, 8B, and 8C) may overlap the wiring WL when the display device 1 (FIGS. 8A, 8B, 8C) is not stretched and/or is stretched.

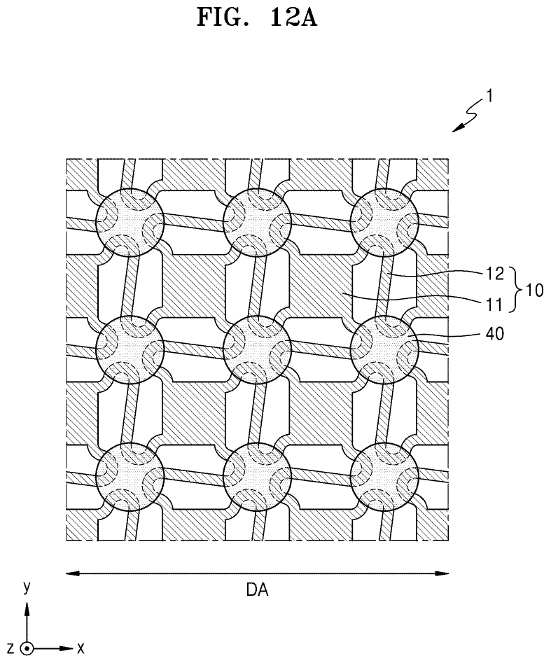

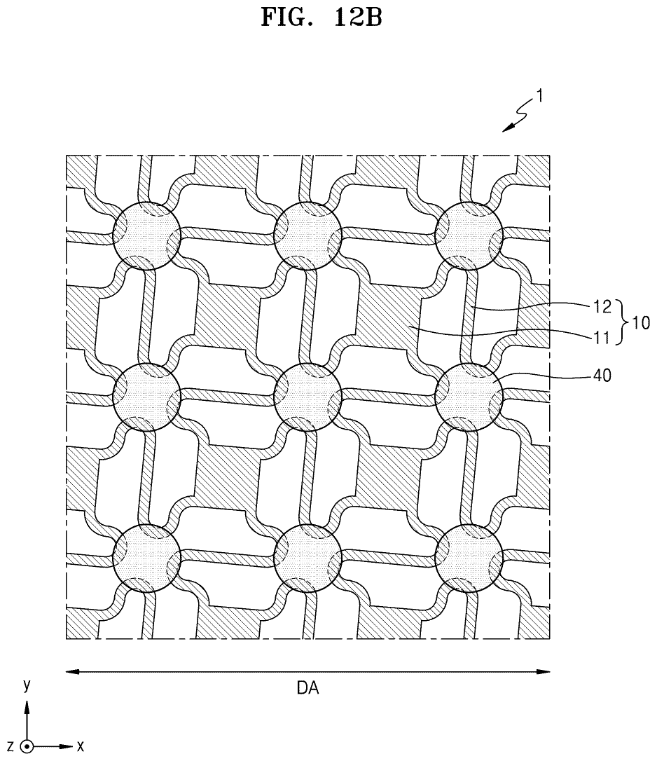

FIG. 12A is a plan view of the display device 1 in a non-stretched state, and FIG. 12B is a plan view of the display device 1 in a stretched state.

Referring to FIG. 12A, in a state where the display device 1 is not stretched (e.g., the display panel 10 is not stretched), the force portion 40 may overlap at least two first bridge portions 12. FIG. 12A illustrates an embodiment where the force portion 40 overlaps adjacent four first bridge portions 12 in the z direction. In an embodiment, for example, the force portion 40 may overlap the curved portion of each of the first bridge portions 12 in the z direction.

Referring to FIG. 12B, in a state where the display device 1 is stretched (e.g., the display panel 10 is stretched), the force portion 40 may overlap the same number of first bridge portions 12 as while the display device 1 is not stretched. As described with reference to FIGS. 9A and 9B, the force portion 40 is in contact with the first surface (e.g., upper surface) of the display panel 10 and is not fixed to the first surface of the display panel 10. Accordingly, while the display device 1 is stretched, as a distance between adjacent first bridge portions 12 increases, the area of each first bridge portion 12 overlapping the force portion 40 may be reduced. In such an embodiment, a contact area between the force portion 40 and the first bridge portion 12 in the state where the display device 1 is stretched, may be less than a contact area between the force portion 40 and the first bridge portion 12 in the state where the display device 1 is not stretched.

In the state where the display device 1 is stretched, because the force portion 40 still overlaps an adjacent first bridge portion 12 and exerts force the first bridge portion 12, the force portion 40 may reduce twisting of the first bridge portion 12, thereby effectively preventing the first bridge portion 12 from being disconnected by the twisting of the first bridge portion 12, and effectively preventing damage to the wiring WL (FIG. 11) of the first bridge portion 12.

FIGS. 13A to 13E are cross-sectional views showing processes corresponding to a method of manufacturing the force portion 40 according to an embodiment of the invention.

Referring to FIGS. 13A and 13B, in an embodiment, a layer (referred to as a second polymer layer 41L, hereinafter) including the second polymer material may be formed on a carrier substrate CA. The second polymer layer 41L may be a type of sacrificial layer or auxiliary layer for removing the force portion from the carrier substrate CA in a process described below.

As shown in FIG. 13A, the second polymer layer 41L may be formed by coating a second polymer material 41M in the form of fibers. Although a process of electrospinning may be used as the coating, the invention is not limited thereto. In another embodiment, the layer including the second polymer material may be coated on the carrier substrate CA.

The second polymer material may include a polymer whose adhesiveness may be changed by heat or light. In an embodiment, the second polymer material may include a thermo-reactive polymer, such as polycaprolactone (PCL).

Referring to FIG. 13B, in an embodiment, a first polymer layer 40L may be formed by coating the first polymer material on the second polymer layer 41L. The first polymer material may include a polymer cured by heat or light. In an embodiment, FIG. 13B shows a case where the first polymer material includes a polymer cured by UV. The first polymer material may include various types of polymers, such as polymethyl methacrylate (PMMA), acryl-based materials, or epoxy-based materials.

In an embodiment, as shown in FIG. 13C, the force portions 40 may be formed by radiating an ultraviolet ray to the remaining regions other than positions where the force portions 40 (FIGS. 8A, 8B, and 8C) are to be formed, and then removing the portions exposed to the ultraviolet ray.

The force portions 40 may be separated and apart from each other. Each force portion 40 includes the first polymer material and may further include a layer (referred to as an auxiliary layer 41, hereinafter) including the second polymer material. In other words, the force portion 40 may have a stack structure of a main layer including the first polymer material and the auxiliary layer 41 including the second polymer material. The auxiliary layer 41 may be formed by the process described above with reference to FIG. 13A, and in this case, gaps between the fibrous mesh structures of the auxiliary layer 41 may be filled with the first polymer material.

Referring to FIG. 13D, the first adhesive layer 20 may be formed by coating an adhesive material on the force portions 40. The material of the first adhesive layer 20 may include a pressure sensitive adhesive (PSA), an optical clear adhesive (OCA), or an optical clear resin (OCR). An upper protective film PV may be formed on the first adhesive layer 20.

A structure on the carrier substrate CA shown in FIG. 13B may be heated at a selected temperature. Adhesive force of the auxiliary layer 41 with respect to the carrier substrate CA may be reduced by heat. Accordingly, the force portion 40 including the auxiliary layer 41 may be separated from the carrier substrate CA.

Referring to FIG. 13E, a lower protective film UPV may be formed on the structure separated from the carrier substrate CA.

In the process of manufacturing the display device 1 (FIG. 9B), the upper protective film PV and the lower protective film UPV may be removed, and the force portion 40 including the auxiliary layer 41 may be disposed on the display panel 10 (FIG. 9B). The force portion 40 including the auxiliary layer 41 may be embedded in the first adhesive layer 20.

FIG. 14A is a schematic perspective view of an electronic apparatus 1000 including the display device according to an embodiment of the invention, and FIG. 14B is a schematic block diagram of the electronic apparatus 1000 including the display device 1 according to an embodiment of the invention.

Referring to FIG. 14A, an embodiment of the electronic apparatus 1000 is freely transformed (or shaped) three-dimensionally, and may provide a three-dimensional image surface through the display area DA. When the electronic apparatus 1000 is freely transformed three-dimensionally, it is distinguished from an operation of an electronic apparatus having a rollable display device such as a case where a portion of a rolled-up display area is visible to a user and then another portion of the rolled-up display area is unfolded so that the entire display area is visible to the user (or a case where the entire unfolded display area is visible to the user and then the display area is rolled-up so that only a portion of the display area is visible to the user). The electronic apparatus 1000 according to embodiments of the invention may represent transformation such as a case where the area of the entire display area DA increases or decreases again while the electronic apparatus 1000 is transformed in the x direction, y direction, and/or z direction.

Referring to FIG. 14B, an embodiment of the electronic apparatus 1000 may include a processor 1100, a memory 1200, an input module 1300, a display module 1400, a power module 1500, a built-in module 1600, and an external module 1700. According to an embodiment, in the electronic apparatus 1000, at least one of the elements may be omitted, or one or more other elements may be added. According to an embodiment, some (e.g., the built-in module 1600) of the elements may be integrated into another element (e.g., the display module 1400).

The processor 1100 may control at least one other element (e.g., a hardware or software element) of the electronic apparatus 1000 connected to the processor 1100 by executing software, and perform various data processes or operations. According to an embodiment, for performing data processes or operations, the processor 1100 may store commands or data received from another element (e.g., the input module 1300, a sensor module 1610, or a communication module 1730) in a volatile memory 1210, process the commands or data stored in the volatile memory 1210, and store result data in a non-volatile memory 1220.

The processor 1100 may include a main processor 1110 and an auxiliary processor 1120. The main processor 1110 may include at least one selected from a central processing unit (CPU) 1111 and an application processor (AP). The main processor 1110 may further include at least one selected from a graphics processing unit (GPU) 1112, a communication processor (CP), and an image signal processor (ISP). The main processor 1110 may further include a neural processing unit (NPU) 1113. The NPU is a processor specialized in processing artificial intelligence models, and the artificial intelligence models may be created through machine learning. The artificial intelligence models may include a plurality of artificial neural network layers. The artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, and a combination of two or more of the above, but is not limited to the examples described above. The artificial intelligence models may additionally or alternatively include a software structure in addition to a hardware structure. At least two selected from the processing units and the processors may be implemented as one integrated construction (e.g., a single chip) or respectively implemented as independent constructions (e.g., a plurality of chips).

The auxiliary processor 1120 may include a controller 1121. The controller 1121 may include an interface conversion circuit and a timing control circuit. The controller 1121 receives image signals from the main processor 1110, converts a data format of image signals to match interface specifications of the display module 1400, and outputs image data. The controller 1121 may output various kinds of control signals used for driving the display module 1400.

The auxiliary processor 1120 may further include a data processing circuit such as a data conversion circuit 1122, a gamma correction circuit 1123, and a rendering circuit 1124. The data conversion circuit 1122 may receive image data from the controller 1121, correct image data such that images are displayed at desired brightness based on characteristics of the electronic apparatus 1000, a user's settings, or the like, or convert image data to reduce power consumption or compensate for an afterimage. The gamma correction circuit 1123 may convert image data, a gamma reference voltage, or the like such that images displayed by the electronic apparatus 1000 have desired gamma characteristics. The rendering circuit 1124 may receive image data from the controller 1121, and render the image data by taking into account the pixel configuration of the display device 1 applied to the electronic apparatus 1000. At least one selected from the data conversion circuit 1122, the gamma correction circuit 1123, and the rendering circuit 1124 may be integrated into another element (e.g., the main processor 1110 or the controller 1121). In an embodiment, the auxiliary processor 1120 may be integrated into a data driver 1430.

The memory 1200 may store various data and input data or output data for commands related thereto, where the various data are used by at least one element (e.g., the processor 1100 or the sensor module 1610) of the electronic apparatus 1000. The memory 1200 may include at least one of the volatile memory 1210 and the non-volatile memory 1220.

The input module 1300 may receive commands or data from the outside (e.g., a user or an external electronic apparatus 2000) of the electronic apparatus 1000, where the commands or data are to be used by the element (e.g., the processor 1100, the sensor module 1610, or a sound output module 1630) of the electronic apparatus 1000.

The input module 1300 may include a first input module 1310 to which commands or data from a user are input, and a second input module 1320 to which commands or data from the external electronic apparatus 2000 are input.

The first input module 1310 may include a microphone, a mouse, a keyboard, or a pen (e.g., a passive pen or active pen). The first input module 1310 may include a mechanical input means such as buttons, a dome switch, a jog wheel, a jog switch, and the like, or a touch input means located on the lower surface or the lateral surface of the electronic apparatus 1000. The touch input means may include the touchscreen layer of the display device 1.

The second input module 1320 may be connected to various kinds of external electronic apparatuses 2000 connected to the electronic apparatus 1000 via wires or wirelessly. In an embodiment, the second input module 1320 may include a high definition multimedia interface (HDMI), a universal serial bus (USB) interface, a secure digital (SD) card interface, or an audio interface. The second input module 1320 may include a connector that may physically connect the electronic apparatus 1000 to the external electronic apparatus 2000, where the connector includes an HDMI connector, a USB connector, an SD card connector, or an audio connector (e.g., a headphone connector). The electronic apparatus 1000 may perform appropriate control related to the connected external electronic apparatus 2000 in response to the external electronic apparatus 2000 being connected to the second input module 1320.

The display module 1400 provides a user with visual information. The display module 1400 may include the display device 1, a scan driver 1420, and the data driver 1430.

The display device 1 displays (outputs) information processed by the electronic apparatus 1000. The display device 1 may display execution screen information of an application driven in the electronic apparatus 1000, or user interface (UI) and graphic user interface (GUI) information corresponding to the execution screen information.

The scan driver 1420 may be mounted on the display device 1 as a driving chip. Alternatively, the scan driver 1420 may be directly formed on the display device 1. In an embodiment, for example, the scan driver 1420 may include an amorphous silicon thin-film transistor (TFT) gate driver circuit (ASG), a low temperature polycrystalline silicon (LTPS) TFT gate driver circuit, or an oxide semiconductor TFT gate (OSG) driver circuit embedded in the display device 1. The scan driver 1420 receives control signals from the controller 1121 and outputs scan signals to the display device 1 in response to control signals.

The display device 1 may further include an emission control driver. The emission control driver outputs an emission control signal to the display device 1 in response to a control signal received from the controller 1121. The emission control driver may be formed separately from the scan driver 1420 or integrated in the scan driver 1420.

The data driver 1430 receives a control signal from the controller 1121, converts image data into a data voltage in the form of an analog voltage in response to a control signal, and outputs data voltages to the display device 1.

The data driver 1430 may be integrated into some elements of the auxiliary processor 1120. In an embodiment, for example, the data driver 1430 may be provided in a timing controller embedded driver IC including the controller 1121.

The power module 1500 supplies power to the elements of the electronic apparatus 1000. The power module 1500 may include a battery charging a power voltage. In addition, the power module 1500 has a connection port, and the connection port may be included in the second input module 1320 to which an external charger that supplies power to charge the battery is connected. Alternatively, the power module 1500 may include a wireless power transmission/reception member to charge the battery wirelessly. The wireless power transmission/reception member may include a plurality of coil-shaped antenna radiators. The power module 1500 may include a power management integrated circuit (PMIC). The PMIC supplies power optimized for each of the elements of the electronic apparatus 1000.

The electronic apparatus 1000 may further include the built-in module 1600 and the external module 1700. The built-in module 1600 may include the sensor module 1610, an antenna module 1620, and the sound output module 1630. The external module 1700 may include a camera module 1710, a light module 1720, and/or the communication module 1730.

The sensor module 1610 may include touch electrodes of the touchscreen layer of the display device 1, and a touch sensor driver. The sensor module 1610 may sense an input due to a user's body or an input due to a pen, and generate an electrical signal or a data value corresponding to the input. The sensor module 1610 may include at least one of a touch sensor 1611, a biometric sensor 1612, and a strain sensor 1613.

The touch sensor 1611 may generate a data value corresponding to coordinate information of an input due to a user's body (e.g., fingers and the like) or an input due to a pen. The touch sensor 1611 may generate, as data values, changes in electrostatic capacity, pressure, or electromagnetism due to an input.

The biometric sensor 1612 may generate data values that recognize a portion of the user's body (e.g., fingerprints, irises, face, and the like) or generate data values corresponding to body information (e.g., blood pressure, moisture, heart rate, body composition, and the like). The biometric sensor 1612 may use an optical method, an ultrasonic method, or a capacitive method.

The strain sensor 1613 may include layers, patterns or wirings in which a measurable physical quantity changes according to the stretching of the display device 1 (e.g., stretching of the display panel). In an embodiment, for example, the strain sensor 1613 may include wirings in which a pressure, a resistance, and/or a capacitance changes due to the stretching of the display device 1 (e.g., stretching of the display panel). In another embodiment, the strain sensor 1613 may include optical layers or optical patterns in which a transmittance and/or reflectivity changes due to the stretching of the display device 1.

The electronic apparatus 1000 may improve the quality of images implemented by the display device 1 or control the display device 1 based on physical quantity changes due to the stretching of the display device 1 measured by the strain sensor 1613. Control operations of the display device 1 may include operations such as displaying an operation image for protecting the display device 1, blocking voltages for driving the display device 1, or stopping a stretching operation of the display device 1.

In an embodiment, at least one of the touch sensor 1611, the biometric sensor 1612, and the strain sensor 1613 may be built into the display device 1. In an embodiment, for example, at least one of the touch sensor 1611, the biometric sensor 1612, and the strain sensor 1613 may be formed during a process that is successive to the process of forming the pixel driving circuit portion and/or the light-emitting element of the display device 1. Accordingly, the display device 1 may serve as one of the input modules 1300 that provide an input interface between the electronic apparatus 1000 and a user, and simultaneously, serve as the display module 1400 that provides an output interface between the electronic apparatus 1000 and a user.

In an embodiment, at least two selected from the touch sensor 1611, the biometric sensor 1612, and the strain sensor 1613 may be formed to be integrated in one sensing panel through a same process. In an embodiment, although the sensing panel may be disposed between the display device 1 and a window cover disposed on a front surface of the display device 1, the invention is not limited thereto.

The antenna module 1620 may include one or more antennas for transmitting signals or power to the outside or receiving signals or power from the outside. In an embodiment, the communication module 1730 may transmit signals to an external electronic apparatus or receive signals from an external electronic apparatus through an antenna suitable for a communication method. An antenna pattern of the antenna module 1620 may be integrated in one element (e.g., the display device 1) of the display module 1400 or the input sensor 1612.

The sound output module 1630 is a device for outputting sound signals to the outside of the electronic apparatus 1000, and may output sound data received from the communication module 1730 or stored in the memory 1200 during call signal reception, a communication mode or recording mode, a voice recognition mode, a broadcasting reception mode, and the like. The sound output module 1630 may output sound signals related to a function (e.g., call signal reception tone, a message reception tone, and the like) performed by the electronic apparatus 1000. The sound output module 1630 may include a receiver and a speaker. At least one selected from the receiver and the speaker may be a sound generator that is attached on the backside of the display device 1 and vibrates the display device 1 to output sounds. The sound generator may be a piezoelectric element or a piezoelectric actuator that contracts and expands according to electrical signals, or an exciter that generates magnetic force by using a voice coil to vibrate the display device 1.

The camera module 1710 may capture still images and moving images. In an embodiment, the camera module 1710 may include one or more lenses, an image sensor, or an image signal processor. The camera module 1710 may further include an infrared camera that may measure whether a user is present, a user's position, a user's gaze, and the like.

The light module 1720 may output signals for informing occurrence of an event using light of a light source, or provide light to obtain images. Here, examples of event occurrence include message reception, call signal reception, a missed call, an alarm, a calendar reminder, receiving an email, being notified of battery charge information, and the like. The light module 1720 may include a light-emitting diode or a xenon lamp. The light module 1720 may emit light of a single color or multiple colors to the front side or backside of the electronic apparatus 1000. The light module 1720 may operate in cooperation with the camera module 1710 or independently.

The communication module 1730 may establish a wired or wireless communication channel between the electronic apparatus 1000 and the external electronic apparatus 2000, and perform communication through the established communication channel. The communication module 1730 may include one or both of a wireless communication module, such as a cellular communication module, a short-range wireless communication module, or a global navigation satellite system (GNSS) communication module, and a wired communication module, such as a local area network (LAN) communication module, or a power line communication module. The communication module 1730 may transmit and receive wireless signals on the Internet using at least one of a wireless LAN) (WLAN), wireless-fidelity (Wi-Fi), Wi-Fi direct, and digital living network alliance (DLNA) technologies. In addition, the communication module 1730 may support short-range communication using at least one of Bluetooth™, RFID radio frequency identification (RFID), infrared data association (IrDA), ultra-wideband (UWB), ZigBee, near field communication (NFC), Wi-Fi, Wi-Fi Direct, and wireless universal serial bus (USB) technologies. The above-described various kinds of communication modules 1730 may be implemented in one chip or respectively implemented as separate chips.

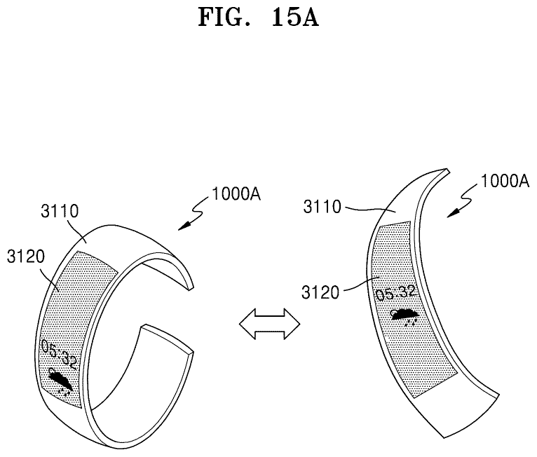

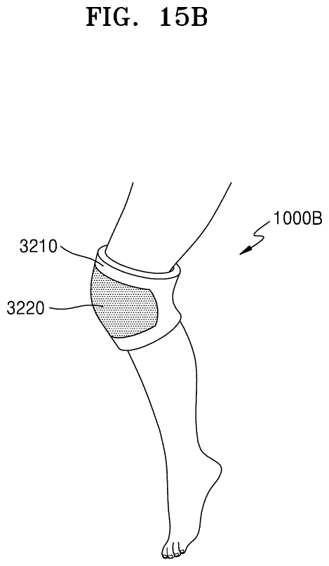

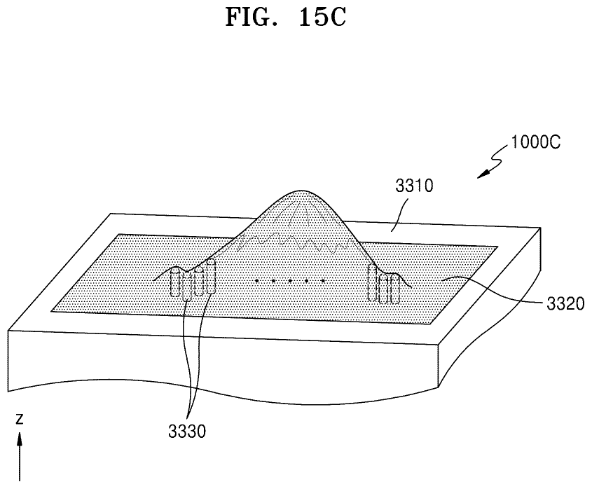

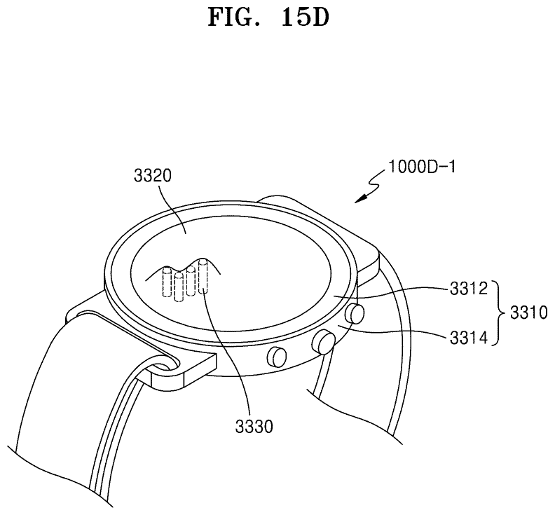

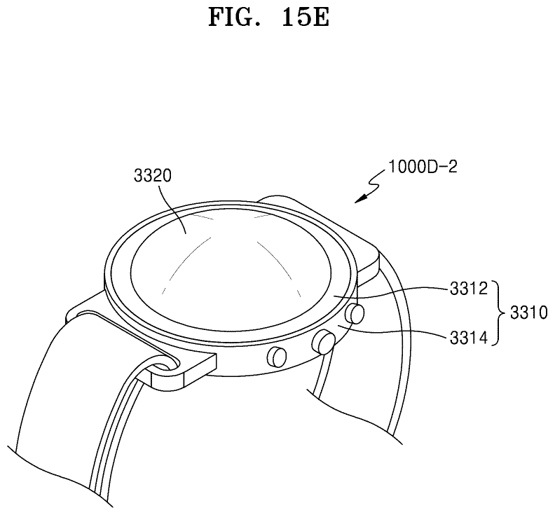

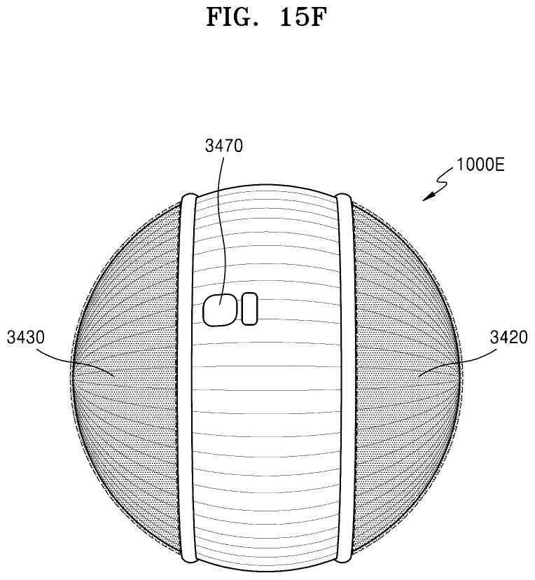

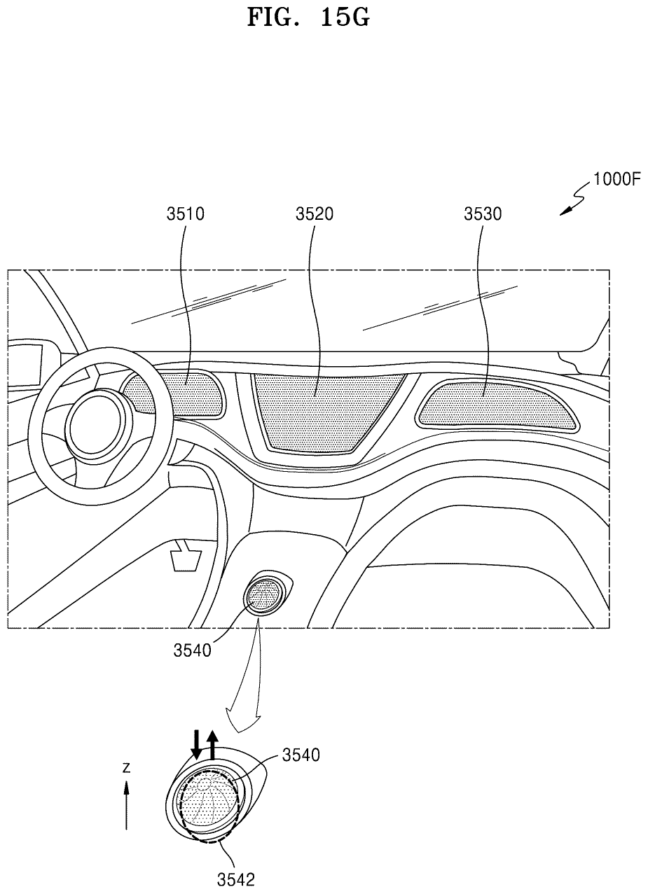

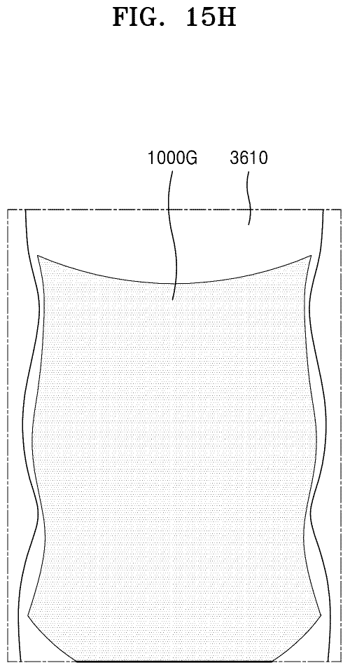

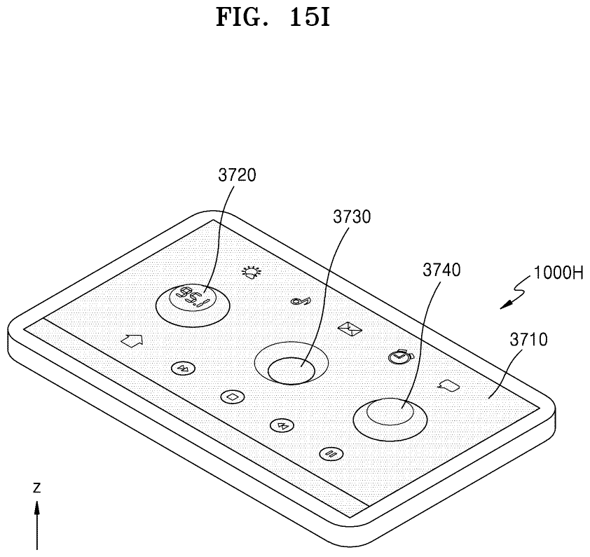

FIGS. 15A to 15D are respectively schematic perspective views of an electronic apparatus including a display device according to an embodiment of the invention.

Referring to FIG. 15A, the display device according to an embodiment of the invention may be utilized in a wearable electronic apparatus 1000A that may be worn on a portion of a user's body. The wearable electronic apparatus 1000A may include a body portion 3110 and a display portion 3120 provided to the body portion 3110. The display device according to embodiments may be used as the display portion 3120 of the wearable electronic apparatus 1000A. As shown in FIG. 15A, the wearable electronic apparatus 1000A may be transformed. In an embodiment, the wearable electronic apparatus 1000A may be used as a smartwatch or a smartphone according to a user's selection.

FIG. 15B shows a medical electronic apparatus 1000B. In an embodiment, the medical electronic apparatus 1000B may include a body portion 3210 and a light-emitting portion 3220. The display device according to embodiments of the invention may be used as the light-emitting portion 3220 of the medical electronic apparatus 1000B. The light-emitting portion 3220 may emit light (e.g., infrared rays, visible rays, and the like) in a preset wavelength band to a patient's body. In an embodiment, the body portion 3210 may include a stretchable fiber material and have a structure that may be worn on the body of a user.

FIG. 15C shows an educational electronic apparatus 1000C. In an embodiment, the educational electronic apparatus may include a display portion 3320 provided inside a housing 3310. The display portion 3320 may be used as the display device according to the embodiments of the invention. An image such as a sea with crashing waves, a snow-covered mountain, or a volcano with flowing lava can be provided through the display portion 3320, and in this case, the display portion 3320 may be stretched in a height direction (e.g., z direction) to reflect the height of the wave, mountain, or volcano. In an embodiment, a portion of the display portion 3320 may be configured to sequentially change its height in a direction in which the lava flows, thereby showing the movement of the lava three dimensionally. The educational electronic apparatus 1000C may include a plurality of pins 3330 (or a stroke portion) disposed on the rear surface of the display portion 3320 such that the display portion 3320 is stretched in the height direction. The pins 3330 may be implemented to move in the third direction (e.g., z direction or-z direction) such that an image expressed on the display portion 3320 has a height three dimensionally. Although FIG. 15C shows an embodiment where the electronic apparatus is the educational electronic apparatus 1000C, the purpose thereof is not limited thereto as far as the educational electronic apparatus provides preset image information.

FIGS. 15D and 15E show the display device is used in wearable electronic apparatuses 1000D-1 and 1000D-2 such as a smartwatch.

In an embodiment, as shown in FIG. 15D, because the display device corresponding to the display portion 3320 of the electronic apparatus 1000D-1 is stretchable three-dimensionally, the display panel may provide, to a user, various haptic information in addition to visual information through images. In an embodiment, the electronic apparatus 1000D-1 may provide haptic information, such as Braille display for the visually impaired or tactile stimulation linked to an image, by using a plurality of pins 3330 (or stroke portions) disposed below the display portion 3320. Because the display panel forming the display portion 3320 is stretchable three-dimensionally, the display device may provide the haptic information to a user. The electronic apparatus 1000D-1 may include the body portion 3310, where the body portion 3310 includes a housing 3314 in which the display device forming the display portion 3320 and the pins 3330 (or stroke portions) are accommodated, and a frame 3312 that may be coupled to the housing 3314 with the display device therebetween. In an embodiment, the frame 3312 may be integrally formed with the housing 3314 as a single unitary indivisible part.

The electronic apparatus 1000D-2 of FIG. 15E may include the body portion 3310 and the display portion 3320 accommodated in the body portion 3310 and providing visual information as in FIG. 15D. In an embodiment, because the display device corresponding to the display portion 3320 is stretchable three-dimensionally, the display panel may include the display portion 3320 of a dome shape. In an embodiment, the display device may be assembled to the body frame of a dome shape during the process of manufacturing the electronic apparatus 1000D-2, and in this case, because the display device is stretchable three-dimensionally, the display device may be assembled while being stretched along the shape of the hemispherical body frame.

FIG. 15F shows an electronic apparatus 1000E according to an embodiment implemented as a robot. The robot may recognize a movement or object using a camera module 3470 and display preset images to a user through display portions 3420 and 3430.

In an embodiment, because the display devices according to an embodiment of the invention may be stretched in various directions as described above, the display devices may be assembled to the body frame having a hemispherical shape, and thus, the robot may include the display portions 3420 and 3430 of a hemispherical shape.

FIG. 15G shows a vehicle display device 1000F as an electronic apparatus according to an embodiment of the invention. The vehicle display device 1000F may include a cluster 3510, a center information display (CID) 3520, and/or a co-driver display 3530. Because the display device according to an embodiment may be stretched in various directions, the display device may be used in the cluster 3510, the CID 3520, and/or the co-driver display 3530 without being restricted by the shape of an internal frame of the vehicle.

Although FIG. 15H shows an embodiment where the cluster 3510, the CID 3520, and/or the co-driver display 3530 are separated from each other, the disclosure is not limited thereto. In another embodiment, two or more selected from the cluster 3510, the CID 3520, and the co-driver display 3530 may be integrally connected.

In an embodiment, the vehicle display device 1000F may include a button 3540 that may express preset images. Referring to an enlarged view of FIG. 15H, the button 3540 of a hemispherical shape may include an object 3542 and a display device disposed on the object 3542, where the object 3542 provides the feel of a button while moving in the z direction or-z-direction. In an embodiment, where the object 3542 has a three-dimensionally round surface, the display device may also have a three-dimensionally round surface.

FIG. 15H shows an electronic apparatus according to an embodiment is an electronic apparatus 1000G for advertising or display. In an embodiment, the electronic apparatus 1000G for advertising or display may be installed on a fixed structure 3610 such as a wall or pole. In an embodiment where the structure 3610 includes an uneven surface as shown in FIG. 15H, the electronic apparatus 1000G for advertising or display may be also disposed along the uneven surface of the structure 3610. In an embodiment, the electronic apparatus 1000G for advertising or display may be installed on the structure 3610 using a heat shrink film.

FIG. 15I shows an electronic apparatus 1000H according to an embodiment is a controller. The controller may include an image-type button. In an embodiment, for example, the controller may include first to third button regions 3720, 3730, and 3740 in which a portion of the display portion 3710 protrudes in the z direction or protrudes in the −z direction (or is recessed in the z direction). In an embodiment, the first and third button regions 3720 and 3740 may protrude in the z direction, and the second button region 3730 may protrude in the −z direction (or be recessed in the z direction).

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
island portions each including a light-emitting element and a pixel driving circuit electrically connected to the light-emitting element;
bridge portions each connected between two adjacent island portions among the island portions; and
force portions apart from each other in a plan view,
wherein a first force portion among the force portions overlaps at least two bridge portions adjacent to each other among the bridge portions in the plan view.

2. The display device of claim 1, wherein a modulus of the first force portion is greater than a modulus of each of the at least two bridge portions.

3. The display device of claim 1, wherein a modulus of the first force portion is greater than about 27 MPa and equal to or less than about 12 GPa.

4. The display device of claim 1, wherein the first force portion includes a first polymer material.

5. The display device of claim 4, wherein the first force portion further includes a layer including a second polymer material different from the first polymer material.

6. The display device of claim 5, wherein
the first polymer material includes an ultraviolet (UV)-curable polymer, and
the second polymer material includes a thermo-reactive polymer.

7. The display device of claim 1, wherein
the display device is stretchable, and
an overlapping area of the first force portion and the at least two bridge portions when the display device is in a stretched state is less than an overlapping area of the first force portion and the at least two bridge portions when the display device is in a non-stretched state.

8. The display device of claim 1, wherein
each of the bridge portions includes a straight portion and a curved portion, and
the first force portion overlaps the curved portion of each of the at least two bridge portions in the plan view.

9. The display device of claim 8, wherein each of the bridge portions includes:
a first curved portion connected to one of the two adjacent island portions;
a second curved portion connected to the other of the two adjacent island portions; and
the straight portion connecting the first curved portion and the second curved portion to each other.

10. The display device of claim 1, further comprising:
an upper protective layer disposed on the force portions,
wherein the upper protective layer includes elastomer.

11. The display device of claim 10, further comprising:
a first adhesive layer disposed between the force portions and the upper protective layer,
wherein the first adhesive layer includes an adhesive material.

12. The display device of claim 11, wherein the force portions are disposed in the first adhesive layer.

13. An electronic apparatus including a display device, wherein the display device comprises:
a display panel including island portions and bridge portions each connected between two adjacent island portions among the island portions; and
force portions arranged on the display panel and apart from each other in a plan view,
wherein each of the bridge portions includes a curved portion and a straight portion, and
wherein a first force portion among the force portions overlaps the curved portion of each of at least two bridge portions adjacent to each other among the bridge portions in the plan view.

14. The electronic apparatus of claim 13, wherein a modulus of the first force portion is greater than a modulus of each of the at least two bridge portions.

15. The electronic apparatus of claim 13, wherein a modulus of the first force portion is greater than about 27 MPa and equal to or less than about 12 GPa.

16. The electronic apparatus of claim 13, wherein
the display panel is stretchable, and
an overlapping area of the first force portion and the at least two bridge portions when the display panel is in a stretched state is less than an overlapping area of the first force portion and the at least two bridge portions when the display device is in a non-stretched state.

17. The electronic apparatus of claim 13, wherein the display device further comprises an upper protective layer disposed on the force portions and including elastomer.

18. The electronic apparatus of claim 17, wherein the display device further comprises a first adhesive layer disposed between the force portions and the upper protective layer, wherein the first adhesive layer includes an adhesive material.

19. The electronic apparatus of claim 18, wherein the force portions are disposed in the first adhesive layer.

20. The electronic apparatus of claim 13, further comprising:
a strain sensor which measures changes in a physical quantity according to stretching of the display panel.
